(19) United States
(12) Patent Application Publication
(10) Pub. No.: US 2024/0373696 A1
(43) Pub. Date: Nov. 7, 2024

(54) DISPLAY DEVICE

(71) Applicant: Samsung Display Co., Ltd., Yongin-si (KR)

(72) Inventors: Jong Seok Kim, Yongin-Si (KR); Dong Hyun SON, Yongin-Si (KR); Sae Bom AHN, Yongin-Si (KR); Seong Jun LEE, Yongin-Si (KR); Ki Young KIM, Yongin-Si (KR)

(21) Appl. No.: 18/586,067

(22) Filed: Feb. 23, 2024

(30) Foreign Application Priority Data
May 2, 2023 (KR) 10-2023-0056832

(51) Int. Cl. H10K 59/131; H10K 59/122; H10K 59/35; H10K 59/40; H10K 59/80

(52) U.S. Cl. CPC H10K 59/131; H10K 59/122; H10K 59/352; H10K 59/40; H10K 59/873

(57) ABSTRACT

A display device is disclosed that includes a substrate including a main region and a sub-region, the main region includes a display area in which pixels are arranged and a first non-display area around the display area, the sub-region protrudes from one side of the main region and includes a second non-display area, a circuit layer disposed on the substrate, a light emitting element layer disposed on the circuit layer, an encapsulation layer disposed on the light emitting element layer, a sensor layer disposed on the encapsulation layer, a bank located in a boundary region which is at or near where the first non-display area meets the second non-display area, a conductive pattern disposed on at least one end of the bank and extending outward from the bank, and a wire disposed in the circuit layer and connected from the sub-region to the main region. The wire passes through a region between an edge of the substrate and the conductive pattern and is spaced apart from the conductive pattern in a plan view.

### CROSS-REFERENCE TO RELATED APPLICATION

This application claims priority from Korean Patent Application No. 10-2023-0056832 filed on May 2, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Description of the Related Art

The importance of display devices has steadily increased with the development of multimedia technology. Accordingly, various types of display devices such as a liquid crystal display device, an organic light emitting display device and the like have been developed.

### SUMMARY

Aspects of the present disclosure may provide a display device capable of preventing damage caused by static electricity.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a substrate including a main region and a sub-region, the main region includes a display area in which pixels are arranged and a first non-display area around the display area, the sub-region protrudes from one side of the main region and includes a second non-display area, a circuit layer disposed on the substrate, a light emitting element layer disposed on the circuit layer, an encapsulation layer disposed on the light emitting element layer, a sensor layer disposed on the encapsulation layer, a bank located in a boundary region which is at or near where the first non-display area meets the second non-display area, a conductive pattern disposed on at least one end of the bank and extending outward from the bank, and a wire disposed in the circuit layer and connected from the sub-region to the main region. The wire passes through a region between an edge of the substrate and the conductive pattern and is spaced apart from the conductive pattern in a plan view.

In an embodiment, the wire may be spaced apart from the conductive pattern by a distance of 3 μm or more in the plan view.

In an embodiment, the sub-region may further include a pad area located in the second non-display area, and the wire may be connected from a pad located in the pad area to the first non-display area via the second non-display area and may not overlap the bank and the conductive pattern.

In an embodiment, the second non-display area may include a bending area spaced apart from the main region and in which the substrate is bent.

In an embodiment, each of the pixels may include a transistor disposed in the circuit layer and including a gate electrode, a source electrode, and a drain electrode, and a light emitting element disposed in the light emitting element layer and electrically connected to the transistor, and the wire may include a first sub-line located between the main region and the bending area and formed from a same layer as the gate electrode.

In an embodiment, at least a part of the conductive pattern and the bank may be located between the main region and the bending area, and the first sub-line may pass through an edge region of the second non-display area by bypassing an area where the bank and the conductive pattern are disposed.

In an embodiment, the circuit layer may further include a connection electrode disposed on the transistor and electrically connecting the transistor to the light emitting element, and the wire may further include a second sub-line located in the bending area and formed from a same layer as the connection electrode.

In an embodiment, a part of the encapsulation layer may be located on the bank and may include an inclined portion by the bank, and the conductive pattern may be disposed on the inclined portion of the encapsulation layer.

In an embodiment, the sensor layer may include sensing patterns disposed on the encapsulation layer, and the conductive pattern may be formed from a same layer as at least one of the sensing patterns and may contain a same material as the at least one sensing pattern.

In an embodiment, the circuit layer may include a first organic layer in the display area, the light emitting element layer may include a second organic layer in the display area, and the bank may include bank layers disposed in the same layer as the first organic layer and the second organic layer, respectively, and overlapping each other.

According to an aspect of the present disclosure, a display device includes a substrate including a main region and a sub-region, the main region includes a display area in which pixels are arranged and a first non-display area around the display area, the sub-region protrudes from a side of the main region and includes a second non-display area, a circuit layer disposed on the substrate, a light emitting element layer disposed on the circuit layer, an encapsulation layer disposed on the light emitting element layer, a sensor layer disposed on the encapsulation layer, a bank located in a boundary region which is at or near where the first non-display area meets the second non-display area, a conductive pattern disposed on at least one end of the bank, and a wire disposed in the circuit layer and connected from the sub-region to the main region via under the bank and the conductive pattern. The bank extends outward from the conductive pattern in a plan view and includes at least one organic layer covering the wire in a region where the wire and the conductive pattern overlap.

In an embodiment, the wire and the conductive pattern may be spaced apart from each other by a distance of 3 μm or more with the at least one organic layer interposed therebetween in a thickness direction of the substrate.

In an embodiment, the circuit layer may include a first organic layer in the display area, the light emitting element layer may include a second organic layer in the display area, and the bank may include bank layers disposed in the same layer as the first organic layer and the second organic layer, respectively, and overlapping each other.

In an embodiment, at least one of the bank layers may completely cover the wire in a region where the wire and the conductive pattern overlap and may extend outward of the conductive pattern in the plan view.

In an embodiment, the second non-display area may include a bending area spaced apart from the main region and in which the substrate is bent.

In an embodiment, at least a part of the conductive pattern and the bank may be located between the main region and the bending area, and the wire may be connected from a pad located in the sub-region to the main region via the bending area and may overlap the bank and the conductive pattern between the main region and the bending area.

In an embodiment, each of the pixels may include a transistor disposed in the circuit layer and including a gate electrode, a source electrode, and a drain electrode, and a light emitting element disposed in the light emitting element layer and electrically connected to the transistor. The wire may include a first sub-line located between the main region and the bending area and formed from a same layer as the gate electrode.

In an embodiment, the circuit layer may further include a connection electrode disposed on the transistor and electrically connecting the transistor to the light emitting element, and the wire may further include a second sub-line located in the bending area and formed from a same layer as the connection electrode.

In an embodiment, a part of the encapsulation layer may be located on the bank and may include an inclined portion at an end of the bank, and the conductive pattern may be disposed on the inclined portion of the encapsulation layer.

In an embodiment, the sensor layer may include sensing patterns disposed on the encapsulation layer, and the conductive pattern may be disposed in the same layer as at least one of the sensing patterns and may contain the same material as the at least one sensing pattern.

The display device according to embodiments may include a conductive pattern disposed on at least one end of a bank. In an embodiment, a wire adjacent to the conductive pattern, e.g., a wire passing through a region between the edge of a substrate and the conductive pattern may be spaced apart from the conductive pattern in plan view. In an embodiment, a wire adjacent to the conductive pattern may pass under the conductive pattern and the bank, and the bank may include at least one organic layer that covers the wire in a region where the wire and the conductive pattern overlap.

According to embodiments, a sufficient separation distance between the conductive pattern and the wire may be secured. Accordingly, wiring defects or damage to the display device caused by static electricity or the like may be prevented or minimized.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating the display device of FIG. 1;

FIG. 3 is a cross-sectional view illustrating an embodiment of a cross section corresponding to line A-A′ of FIG. 2;

FIG. 4 is a plan view illustrating the display panel according to an embodiment;

FIG. 5 is a plan view illustrating the display area according to an embodiment;

FIG. 6 is a cross-sectional view illustrating the display panel according to an embodiment;

FIG. 7 is a plan view schematically illustrating wires according to an embodiment;

FIG. 8 is a cross-sectional view illustrating the display panel according to an embodiment;

FIG. 9 is a plan view schematically showing part E of FIG. 4;

FIG. 10 is a cross-sectional view illustrating an embodiment of a cross section corresponding to line F-F′ of FIG. 9;

FIG. 11 is a plan view illustrating the display panel according to an embodiment;

FIG. 12 is a plan view schematically showing part G of FIG. 11; and

FIGS. 13, 14, 15, 16, 17, 18, 19, 20, and 21 are cross-sectional views illustrating embodiments of a cross section corresponding to line H-H′ of FIG. 12.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Features of each of various embodiments of the present disclosure may be partially or entirely combined with each other and may technically variously interwork with each other, and respective embodiments may be implemented independently of each other or may be implemented together in association with each other.

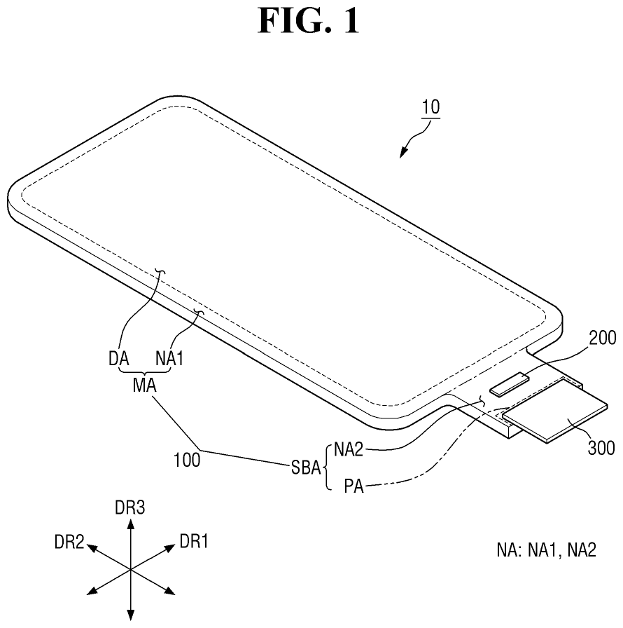

FIG. 1 is a perspective view illustrating a display device 10 according to an embodiment.

Referring to FIG. 1, a display device 10 is a device for displaying a moving image or a still image. The display device 10 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not limited thereto.

The display device 10 may be formed flat. For example, the display device 10 may be formed substantially flat on a plane defined by a first direction DR1 and a second direction DR2, and may have a predetermined thickness (or height) in a third direction DR3. However, embodiments are not limited thereto. For example, the display device 10 may include a curved surface in at least a part including an edge region and the like. In addition, the display device 10 may be formed flexibly so that it can be curved, bent, folded, or rolled.

The display device 10 may include a display panel 100, a display driving circuit 200, and a circuit board 300.

The display panel 100 may include a main region MA including a display area DA in which an image is displayed, and a sub-region SBA protruding from one side of the main region MA.

The main region MA may include a display area DA and a first non-display area NA1 located around the display area DA.

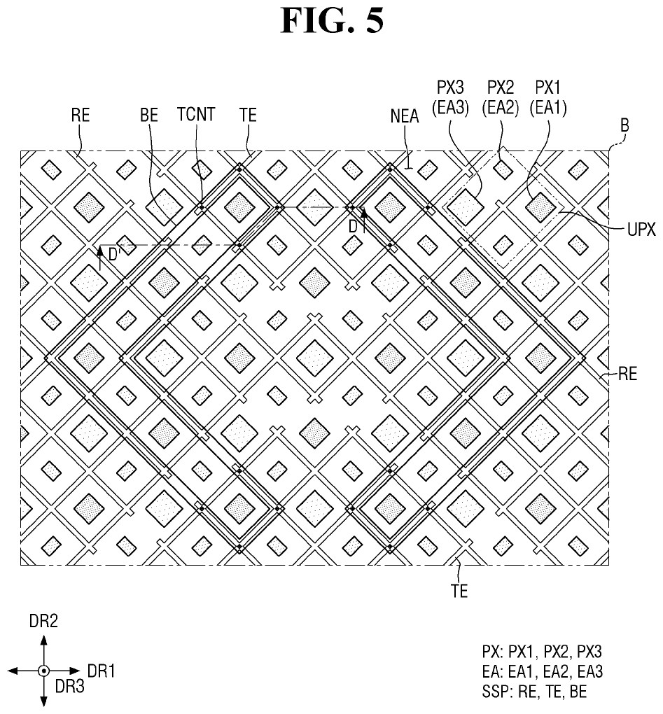

The display area DA may be an area where pixels (e.g., pixels PX in FIG. 5) are arranged and an image is displayed by the pixels PX. In an embodiment, the display area DA may be further provided with sensing patterns, e.g., touch electrodes, for detecting a touch input and the like, and the display area DA may include a sensing area for detecting a touch input by the sensing patterns. The sensing area may be an area where the sensing patterns are disposed, which may be the entire display area DA or a part of the display area DA. Alternatively, the sensing area may be located in a part of a non-display area NA without overlapping the display area DA.

The first non-display area NA1, as a part of the non-display area NA, may be a portion of the main region MA in the non-display area NA. The first non-display area NA1 may be located immediately around the display area DA and may surround the display area DA.

The sub-region SBA may include a second non-display area NA2 and a pad area PA located on the periphery of the second non-display area NA2. For example, the pad area PA may be disposed on a side of the second non-display area NA2.

The second non-display area NA2 may be immediately adjacent to the first non-display area NA1 and the pad area PA. For example, the second non-display area NA2 may be located between the first non-display area NA1 and the pad area PA, and may be in contact with the first non-display area NA1 and the pad area PA. In one example, the first non-display area NA1, the second non-display area NA2, and the pad area PA may be arranged sequentially along the second direction DR2.

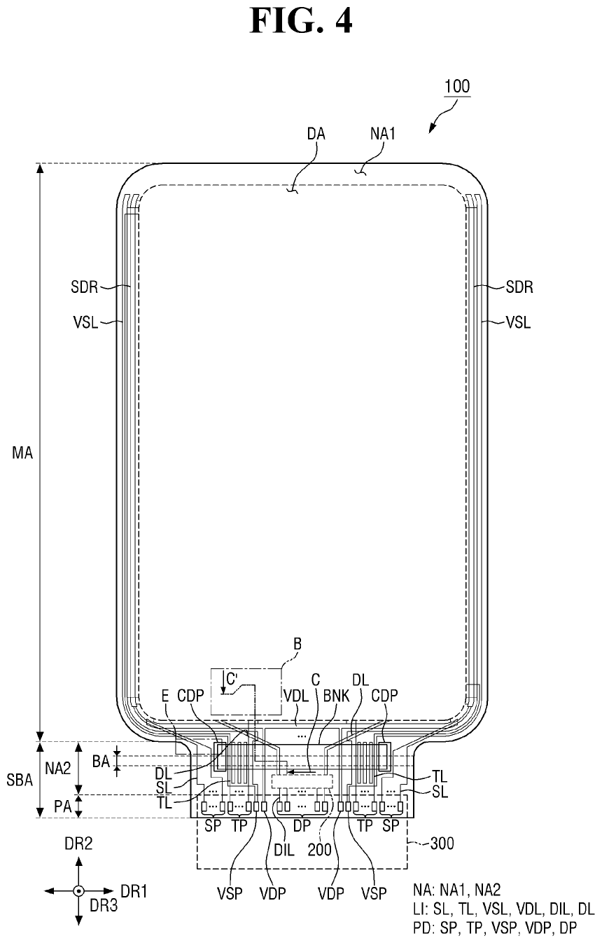

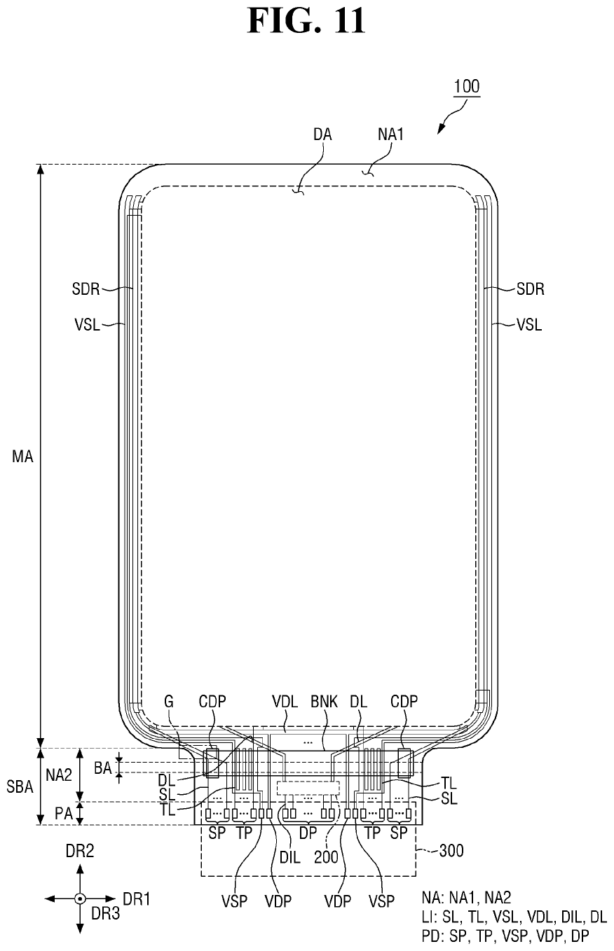

Wires (e.g., wires LI in FIG. 4 or FIG. 11) may be disposed in the second non-display area NA2. In an embodiment, a display driving circuit 200 may be mounted in the second non-display area NA2.

The wires may include power lines and signal lines for connecting each of pads provided in the pad area PA to elements located in the main region MA or the second non-display area NA2. The wires may further include signal lines for connecting the display driving circuit 200 to elements of the main region MA. In describing embodiments, the term “connect” may include electrical connection or physical connection.

For example, the wires may include power lines and signal lines, which are connected the pixels in the display area DA, the sensing patterns in the display area DA, an embedded circuit (e.g., scan driving circuit) in the first non-display area NA1, or the display driving circuit 200 in the second non-display area NA2. In addition, the wires may include signal lines (e.g., data lines DL of FIG. 4 or 11) that connect the display driving circuit 200 to the pixels of the display area DA.

The display driving circuit 200 may be implemented as an integrated circuit chip (IC) and mounted in the sub-region SBA. In one example, the display driving circuit 200 may be mounted in the second non-display area NA2. The display driving circuit 200 may include a data driving circuit for driving the pixels and may supply data signals to data lines that extend from the second non-display area NA2 to the display area DA.

The circuit board 300 may be disposed on the pad area PA of the sub-region SBA. The circuit board 300 may be bonded to the pads provided in the pad area PA, and may supply or transmit driving power and driving signals to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but is not limited thereto.

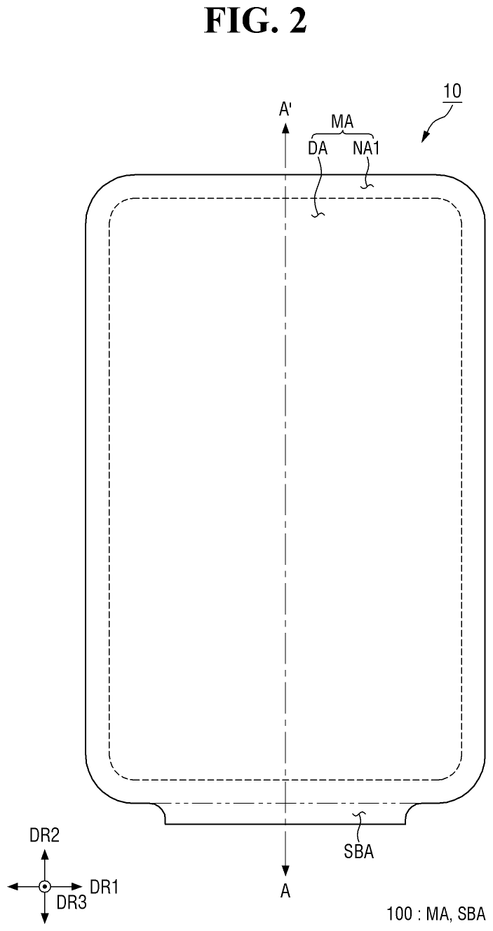

FIG. 2 is a plan view illustrating the display device 10 of FIG. 1. FIG. 1 shows the display device 10 unfolded without bending, and FIG. 2 shows the display device 10 bent in the sub-region SBA. For example, FIG. 1 shows the sub-region SBA unfolded alongside the main region MA, and FIG. 2 shows a part of the sub-region SBA in a bent state.

Referring to FIGS. 1 and 2, the display area DA may be formed as a plane having a roughly rectangular shape, including short sides in the first direction DR1 and long sides in the second direction DR2 intersecting the first direction DR1. A corner portion where the short side in the first direction DR1 and the long side in the second direction DR2 meet may be rounded or right-angled. The shape of the display area DA in plan view is not limited to a rectangular shape, but may be formed in another polygonal shape, a circular shape, an elliptical shape, or the like.

The display area DA may occupy most of the main region MA. The display area DA may be disposed at the center of the main region MA.

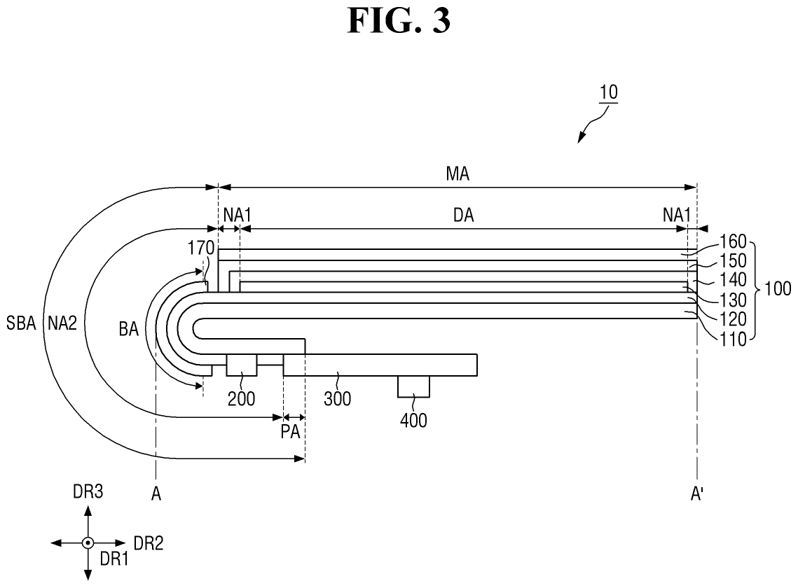

FIG. 3 is a cross-sectional view illustrating an embodiment of a cross section corresponding to line A-A′ of FIG. 2.

Referring to FIGS. 1 to 3, the display panel 100 of the display device 10 may include a substrate 110 including the main region MA and the sub-region SBA, a circuit layer 120 disposed on the substrate 110, a light emitting element layer 130 disposed on the circuit layer 120, and an encapsulation layer 140 disposed on the light emitting element layer 130. In an embodiment, the display panel 100 may further include a sensor layer 150 (e.g., touch sensor layer) and a polarization layer 160 disposed on the encapsulation layer 140.

The substrate 110 may include an insulating material such as a polymer resin. For example, the substrate 110 may be made of polyimide or another insulating material. The substrate 110 may be a flexible substrate that can be transformed, such as bending, folding, or rolling. Alternatively, the substrate 110 may include an insulating material such as glass.

The circuit layer 120 may include circuit elements (e.g., transistors and capacitors) constituting a pixel circuit for each pixel, and wires connected to the pixels. In an embodiment, the circuit layer 120 may further include circuit elements constituting an embedded circuit, such as a scan driving circuit, and wires connected to the embedded circuit.

The light emitting element layer 130 may include light emitting elements provided in emission areas of the pixels. For example, each pixel may include at least one light emitting element and a pixel circuit connected to the light emitting element. Each pixel may be located in a pixel region, including the emission area where the light emitting element is disposed and a pixel circuit area where the pixel circuit is disposed. In an embodiment, the emission area and the pixel circuit area of each pixel may overlap each other, but the present disclosure is not limited thereto.

The encapsulation layer 140 may cover the light emitting element layer 130 and may extend to the non-display area NA to be in contact with the circuit layer 120. In an embodiment, the encapsulation layer 140 may have a multilayer structure with at least two inorganic layers and at least one organic layer alternately stacked.

The sensor layer 150 may include the sensing patterns disposed on the encapsulation layer 140. In an embodiment, the sensor layer 150 may be a touch sensor layer, and the sensing patterns may include touch electrodes for detecting a touch input (direct touch, proximity, or the like) from a person or an object. Wires connected to the sensing patterns in the sensor layer 150 may extend from the main region MA to the sub-region SBA.

The polarization layer 160 may be disposed on the sensor layer 150 (or the encapsulation layer 140). The polarization layer 160 may block external light reflected from the sensor layer 150, the encapsulation layer 140, the light emitting element layer 130, the circuit layer 120, and the interface thereof. Accordingly, deterioration in visibility of an image due to reflection of external light may be prevented.

The display panel 100 may be bent at a bending area BA. The bending area BA may be a part of the second non-display area NA2 of the sub-region SBA and may be spaced apart from the main region MA. For example, the substrate 110 and the circuit layer 120 may be bent in the bending area BA corresponding to a part of the second non-display area NA2.

In an embodiment, the display device 10 may further include a passivation layer 170 provided on the circuit layer 120 in the bending area BA. The passivation layer 170 may alleviate the impact caused by bending and prevent or reduce damage to the display panel 100. In an embodiment, the passivation layer 170 may be provided in a region spaced apart from the main region MA in consideration of the slip characteristics of the display panel 100, and may cover the circuit layer 120 and the substrate 110 at least in the bending area BA.

The display device 10 may further include a cover window (not shown) disposed on the polarization layer 160. The cover window may be attached to the polarization layer 160 by a transparent adhesive member such as an optically clear adhesive (OCA) film or an optically clear resin (OCR). Alternatively, the cover window may be manufactured integrally with the display device 10. The cover window may include an inorganic material such as glass or an organic material such as plastic or a polymer material. The cover window may protect the display panel 100 from electrical or physical shock.

In an embodiment, the display device 10 according to an embodiment may further include a touch driving circuit 400 for driving the sensor layer 150. In an embodiment, the touch driving circuit 400 may be implemented as an integrated circuit chip (IC), and may be mounted on the circuit board 300 bonded to the pads in the pad area PA to be electrically connected to the sensor layer 150. Alternatively, similarly to the display driving circuit 200, the touch driving circuit 400 may be mounted on the substrate 110. In one example, the touch driving circuit 400 may be mounted in the second non-display area NA2.

The touch driving circuit 400 may apply a touch driving signal to the sensing patterns provided in the sensor layer 150 and receive a touch sensing signal through the sensing patterns. For example, when the sensor layer 150 includes driving electrodes and sensing electrodes constituting mutual capacitive sensing patterns, the touch driving circuit 400 may apply a touch driving signal to the driving electrodes, receive a touch sensing signal of each of touch nodes through the sensing electrodes, and detect a change in the charge of mutual capacitance based on the touch sensing signal. Accordingly, the touch driving circuit 400 may determine a user's touch or proximity and the location thereof, based on the touch sensing signal of each of the touch nodes.

FIG. 4 is a plan view illustrating the display panel 100 according to an embodiment. FIG. 4 shows the display panel 100 in an unbent and unfolded state.

FIG. 5 is a plan view illustrating the display area DA according to an embodiment. For example, FIG. 5 is a plan view showing part B of FIG. 4.

Referring to FIGS. 4 and 5 in addition to FIGS. 1 to 3, the display panel 100 may include the display area DA located in the main region MA, and the non-display area NA located in the sub-region SBA and the remaining area of the main region MA excluding the display area DA. For example, the non-display area NA may include the first non-display area NA1 located in the main region MA and the second non-display area NA2 located in the sub-region SBA. The non-display area NA may include the bending area BA corresponding to a part of the sub-region SBA. For example, the non-display area NA may include the bending area BA corresponding to a part of the second non-display area NA2 and spaced apart from the main region MA.

Further, the display panel 100 may include the pad area PA located on one side of the non-display area NA. The pad area PA may be located in the sub-region SBA. For simplicity, in FIG. 4, the non-display area NA and the pad area PA are separately defined, but the pad area PA may be considered to correspond to a part of the non-display area NA.

As shown in FIG. 5, the pixels PX and sensing patterns SSP may be disposed in the display area DA. The pixels PX and the sensing patterns SSP may be disposed in different layers in the display panel 100, and may or may not overlap each other. For example, the pixels PX may be provided in the circuit layer 120 and the light emitting element layer 130 of the display panel 100. In one example, each pixel PX may include a pixel circuit including circuit elements provided in the circuit layer 120 and a light emitting element provided in the light emitting element layer 130. The sensing patterns SSP may be provided in the sensor layer 150 overlapping the circuit layer 120 and the light emitting element layer 130.

In an embodiment, the pixels PX may include at least two groups of pixels PX that emit light of different colors. For example, the pixels PX may include first pixels PX1, second pixels PX2, and third pixels PX3 that emit light of different colors. Each first pixel PX1 may include a first emission area EA1, and may emit light of a first color (e.g., red light) from the first emission area EA1. Each second pixel PX2 may include a second emission area EA2, and may emit light of a second color (e.g., green light) from the second emission area EA2. Each third pixel PX3 may include a third emission area EA3, and may emit light of a third color (e.g., blue light) from the third emission area EA3. FIG. 5 illustrates the arrangement structure of the pixels PX based on an emission area EA of each of the pixels PX. The remaining area of the display area DA excluding the emission areas EA of the pixels PX may be a non-emission area NEA.

In an embodiment, the first pixels PX1 and the third pixels PX3 may be alternately arranged in the first direction DR1 and the second direction DR2. The second pixels PX2 may be arranged side by side in the first direction DR1 and the second direction DR2, and may be adjacent to the first pixels PX1 or the third pixels PX3 in a diagonal direction intersecting the first direction DR1 and the second direction DR2.

Each of the emission areas EA of the first pixels PX1, the second pixels PX2, and the third pixels PX3 may have a quadrangular shape, such as a rhombus or rectangle. Alternatively, one or more of the emission areas EA of the first pixels PX1, the second pixels PX2, and the third pixels PX3 may have a shape other than a quadrangular shape.

In an embodiment, at least two of the first pixels PX1, the second pixels PX2, and the third pixels PX3 may include emission areas EA having different sizes. For example, the first pixels PX1, the second pixels PX2, and the third pixels PX3 may be formed to include emission areas EA having different sizes depending on the light efficiency, lifetime, or white balance of the pixels PX.

At least one first pixel PX1, at least one second pixel PX2, and at least one third pixel PX3 adjacent to each other may constitute a unit pixel UPX. In one example, one first pixel PX1, two second pixels PX2, and one third pixel PX3 adjacent to each other may constitute one unit pixel UPX. Each unit pixel UPX may emit light of various colors, including white light, by color mixing of light emitted from the emission areas EA of the pixels PX constituting the unit pixel UPX.

The sensing patterns SSP may be touch electrodes for detecting the user's touch or proximity and the like. In an embodiment, the sensing patterns SSP may be provided only in the display area DA, but are not limited thereto. For example, the sensing patterns SSP may be provided in at least a part of the display area DA and at least a part of the non-display area NA, or may be provided only at least a part of the non-display area NA without being provided in the display area DA.

In an embodiment, the sensing patterns SSP may be touch electrodes constituting a mutual capacitive touch sensor. For example, the sensing patterns SSP may include driving electrodes TE to which driving signals are applied and sensing electrodes RE for detecting a voltage charged by mutual capacitance with the driving electrodes TE. In an embodiment, the sensing patterns SSP may further include bridge electrodes BE for connecting the driving electrodes TE or the sensing electrodes RE in one direction.

The driving electrodes TE and the sensing electrodes RE may be connected along different directions. For example, the driving electrodes TE may be located in each column based on the resolution of the sensor layer 150, and the driving electrodes TE in each column may be connected to each other along the second direction DR2. In one example, the driving electrodes TE in each column may be connected to each other by the bridge electrodes BE along the second direction DR2. The sensing electrodes RE may be located in each row based on the resolution of the sensor layer 150, and the sensing electrodes RE located in each row may be connected to each other along the first direction DR1. In one example, the sensing electrodes RE in each row may be integral with each other.

The driving electrodes TE and the sensing electrodes RE may have a substantially quadrangular shape such as a rhombus or a rectangle. The driving electrodes TE and the sensing electrodes RE may also have a shape other than a quadrangular shape.

The bridge electrodes BE may be disposed in a different layer from the driving electrodes TE and the sensing electrodes RE. The bridge electrodes BE may be electrically connected to the driving electrodes TE through contact portions TCNT including at least one contact hole.

The bridge electrodes BE may have a shape that is substantially bent one or more times. The bridge electrodes BE may have other shapes.

The driving electrodes TE, the sensing electrodes RE, and the bridge electrodes BE may form mesh-shaped electrodes. For example, the driving electrodes TE, the sensing electrodes RE, and the bridge electrodes BE may form mesh-shaped electrodes including openings corresponding to the emission areas EA of the pixels PX. Accordingly, the light loss of the display device 10 may be prevented or reduced, and the light efficiency may be increased.

The display device 10 may include pixels PX and sensing patterns SSP according to various embodiments other than the embodiment shown in FIG. 5. For example, the type, number, resolution, arrangement structure, shape, or size of the pixels PX, the type, number, or ratio of the pixels PX constituting each unit pixel UPX, and the like may be variously changed according to embodiments. In addition, the type, structure, shape, size, arrangement structure, or the like of the sensing patterns SSP may be variously changed according to embodiments.

Referring again to FIG. 4, the wires LI (or a part of the wires LI), a bank BNK, and at least one conductive pattern CDP may be disposed in the non-display area NA. At least some of the wires LI may extend to the display area DA and may be connected to the pixels PX or the sensing patterns SSP. In an embodiment, the display driving circuit 200 may be disposed on a part of the non-display area NA, for example, a part of the second non-display area NA2. In a region where the display driving circuit 200 is disposed, the pads may be disposed to connect at least some of the wires LI to the display driving circuit 200. For example, in the region where the display driving circuit 200 is disposed, input and output pads may be disposed to connect data input lines DIL and the data lines DL to the display driving circuit 200.

In an embodiment, an embedded circuit SDR may be further disposed in the non-display area NA. For example, at least one embedded circuit SDR may be disposed in the first non-display area NA1 of the main region MA. The embedded circuit SDR may be located at one side of the display area DA, or both sides of the display area DA.

The embedded circuit SDR may be formed in the display panel 100 together with the pixels PX. For example, the embedded circuit SDR may include circuit elements (e.g., transistors and capacitors) disposed in the circuit layer 120 of the display panel 100, and may be formed together with the wires LI and the circuit elements that constitute the pixel circuit of the pixels PX. In an embodiment, the embedded circuit SDR may include a gate driving circuit, such as a scan driving circuit, or a part of the gate driving circuit. In another embodiment, the gate driving circuit may be fabricated separately from the display panel 100 and mounted, in the form of an integrated circuit chip, on the display panel 100 or on the circuit board (e.g., circuit board 300) electrically connected to the display panel 100. If the gate driving circuit is not formed in the display panel 100, the gate driving circuit may be integrated into the display driving circuit 200 mounted in the sub-region SBA, or may be fabricated separately from the display driving circuit 200. The gate driving circuit may be connected to the pixels PX through scan lines and the like, and may supply a gate signal (e.g., scan signal) to the above pixels PX.

The wires LI may be located in the first non-display area NA1 or the second non-display area NA2. The wires LI may include various power lines and signal lines connected to the pixels PX, the sensing patterns SSP, the embedded circuit SDR, or the display driving circuit 200. At least some of the wires LI may extend from the pad area PA to the first non-display area NA1 via the second non-display area NA2. At least some of the wires LI extending to the first non-display area NA1 may extend to the display area DA to be connected to the pixels PX or the sensing patterns SSP. Some others of the wires LI may extend from the pad area PA to the second non-display area NA2. Still some others of the wires LI may extend from the second non-display area NA2 to the first non-display area NA1 or the display area DA.

In an embodiment, the wires LI may include first lines SL (e.g., input lines of the scan driving circuit) connected to the embedded circuit SDR, second lines TL (e.g., input and output lines of the sensor layer 150) connected to the sensing patterns SSP, third lines DIL (e.g., data input lines) connected to the display driving circuit 200, the data lines DL connected to the pixels PX, at least one first power line VDL, and at least one second power line VSL.

The first lines SL may be connected between first pads SP (e.g., scan input pads) provided in the pad area PA and the embedded circuit SDR. The first lines SL may transmit input power or control signals to the embedded circuit SDR supplied from the first pads SP.

The second lines TL may be connected between second pads TP (e.g., touch input/output pads) provided in the pad area PA and the sensing patterns SSP. The second lines TL may electrically connect the touch driving circuit (e.g., touch driving circuit 400 of FIG. 3) to the sensing patterns SSP via the second pads TP. By the second lines TL, the touch driving signal from the touch driving circuit 400 may be transmitted to the sensing patterns SSP, and the touch sensing signal generated by the sensing patterns SSP may be transmitted to the touch driving circuit 400.

In an embodiment, some of the second lines TL may overlap the second power line VSL. For example, the second lines TL and the second power line VSL may be adjacent to each other, and the second power line VSL may have a large width such that a part thereof can be positioned below an area where the second lines TL are disposed. That is, some of the second lines TL may be disposed on the second power line VSL. Accordingly, display noise caused by the driving signals for driving the pixels PX may be shielded or reduced from being transmitted to the second lines TL.

The third lines DIL may be connected between third pads DP (e.g., data pads) provided in the pad area PA and the display driving circuit 200 (or input pads of the display driving circuit 200). The third lines DIL may transmit input signals (e.g., input signals including input image data) of the display driving circuit 200 inputted to the third pads DP to the display driving circuit 200.

The data lines DL (or data connection lines) may be connected between the display driving circuit 200 (or output pads of the display driving circuit 200) and the pixels PX. The data lines DL may transmit output signals (e.g., data signals) of the display driving circuit 200 to the pixels PX.

The first power line VDL may be connected between a first power pad VDP provided in the pad area PA and the pixels PX. The first power line VDL may transmit a first power voltage (e.g., high potential driving voltage of the pixels PX) inputted to the first power pad VDP to the pixels PX.

The second power line VSL may be connected between a second power pad VSP provided in the pad area PA and the pixels PX. The second power line VSL may transmit a second power voltage (e.g., low potential driving voltage of the pixels PX) inputted to the second power pad VSP to the pixels PX.

In an embodiment, the first power line VDL and the second power line VSL may be formed to have a relatively large width compared to other wires. In an embodiment, at least one of the first power line VDL and the second power line VSL may be divided into a plurality of lines having a smaller width in the bending area BA.

In an embodiment, a plurality of first power lines VDL and a plurality of second power lines VSL may be formed. Accordingly, voltage drops in the first power line VDL and the second power line VSL may be prevented or reduced, and the first power voltage and the second power voltage may be stably transmitted to the pixels PX. In an embodiment, depending on the structure of the pixels PX, the display panel 100 may further include at least one power line that supplies an additional power voltage.

The bank BNK may be located in the non-display area NA. For example, the bank BNK may be located in a part of the non-display area NA including a boundary region located at or near where the first non-display area NA1 meets the second non-display area NA2. In describing embodiments, the boundary region between the first non-display area NA1 and the second non-display area NA2 may include a tangential region (e.g., boundary between the main region MA and the sub-region SBA) where the first non-display area NA1 and the second non-display area NA2 are in contact with each other, as well as a peripheral region adjacent to the tangential region. For example, the bank BNK may be spaced apart from the display area DA and located in the non-display area NA below the display area DA.

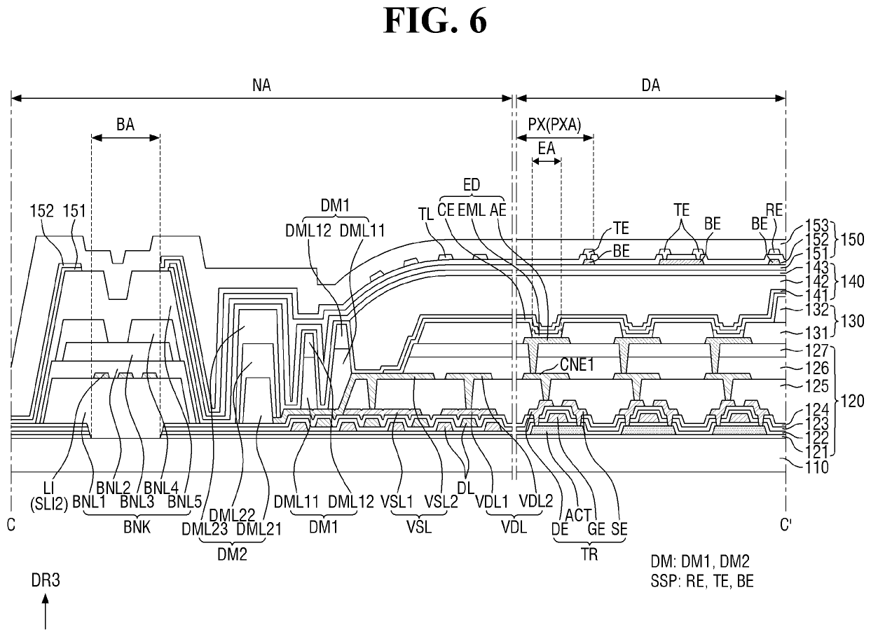

In an embodiment, the bank BNK may overlap one end of the encapsulation layer 140 (e.g., bottom portion of the encapsulation layer 140 in the display area DA). In an embodiment, the display panel 100 may further include at least one dam (e.g., a first dam DM1 or a second dam DM2 of FIG. 6) surrounding the display area DA, and a part of the dam may be located between the display area DA and the bank BNK.

The conductive pattern CDP may be disposed on at least one end of the bank BNK. For example, the conductive pattern CDP may be disposed on both ends (e.g., left and right ends) of the bank BNK in the first direction DR1.

Each conductive pattern CDP may cover the end of the bank BNK and may extend outward of the bank BNK. For example, the conductive pattern CDP may protrude or extend outward of the bank BNK toward the edge region of the second non-display area NA2 in at least the first direction DR1 in plan view.

In an embodiment, the bank BNK may include an inclined portion (or stepped portion) at least at the end where the conductive pattern CDP is formed, and one end of the encapsulation layer 140 and the conductive pattern CDP may be sequentially disposed on the inclined portion of the bank BNK. The conductive pattern CDP may prevent damage to the encapsulation layer 140 during the fabricating process of the display panel 100. For example, the conductive pattern CDP may function as an etch-stopper to prevent damage to the encapsulation layer 140 during an etching process (e.g., etching process for forming the contact portions TCNT) for forming the sensor layer 150. In one example, the conductive pattern CDP may be a capping layer for protecting the encapsulation layer 140.

In an embodiment, the conductive pattern CDP may be formed simultaneously with some of the sensing patterns SSP and may be disposed on the same layer. In one example, the conductive pattern CDP may be formed simultaneously using the same material as patterns (e.g., the bridge electrodes BE) disposed in a lower layer among the sensing patterns SSP.

The shapes, locations, sizes, and the like of the bank BNK and conductive pattern CDP are not limited to those of the embodiment shown in FIG. 4. For example, the bank BNK may be provided in a position where it can partially overlap the encapsulation layer 140, and the shape, location, or size of the bank BNK may be variously changed according to embodiments. Further, the conductive pattern CDP may be provided on at least a part of the bank BNK to cover at least a part of the encapsulation layer 140 located on the bank BNK, and the shape, location, or size of the conductive pattern CDP may be variously changed according to embodiments.

The conductive pattern CDP may be connected to a power line, such as the first power line VDL and the second power line VSL at the outer edge, supplying a constant voltage. Accordingly, it is possible to protect the electric field of wires, such as the first lines SL, located lower than the conductive pattern CDP, block or shield noise, and effectively block static electricity.

Pads PD may be arranged in the pad area PA. For example, the pad area PA may include the first pads SP connected to the first lines SL, the second pads TP connected to the second lines TL, the third pads DP connected to the third lines DIL, the first power pad VDP connected to the first power line VDL, and the second power pad VSP connected to the second power line VSL. The circuit board 300 may be disposed on the pad area PA.

In an embodiment, the third pads DP may be located at the center of the pad area PA, and the first pads SP and the second pads TP may be dividedly disposed to both sides of the third pads DP. In an embodiment, the pad area PA may be provided with two or more first power pads VDP and second power pads VSP, and each of the first power pads VDP and second power pads VSP may be dividedly disposed to both sides of the third pads DP.

The type, location, arrangement order, and number of the pads PD are not limited to those of the embodiment shown in FIG. 4. For example, the type, location, arrangement order, or number of the pads PD may be variously changed according to embodiments.

FIG. 6 is a cross-sectional view illustrating the display panel 100 according to an embodiment. For example, FIG. 6 schematically illustrates an embodiment of a cross section corresponding to line C-C′ of FIG. 4. In FIG. 6, the cross section for the display area DA may correspond to a cross section taken along line D-D′ of FIG. 5.

Although not shown in FIG. 6, an additional layer may be disposed on the sensor layer 150. For example, a polarization layer (e.g., the polarization layer 160 of FIG. 3) or a color filter layer may be disposed on the sensor layer 150. The polarization layer 160 or the color filter layer may be fabricated integrally with the display panel 100, or may be fabricated separately from the display panel 100 and attached to one surface of the display panel 100 by means of an adhesive layer or the like. Outside the polarization layer or the color filter layer, a light blocking pattern (e.g., a single layer or multilayer light blocking pattern including a black matrix, or a multilayer light blocking pattern with at least two color filters, such as a red color filter and a blue color filter, stacked) may be provided.

Referring to FIGS. 1 to 6, the display panel 100 may include the substrate 110, and the circuit layer 120, the light emitting element layer 130, the encapsulation layer 140, and the sensor layer 150 disposed on the substrate 110. The circuit layer 120, the light emitting element layer 130, the encapsulation layer 140, and the sensor layer 150 may be sequentially arranged or stacked in the third direction DR3. First, the structure of the display panel 100 will be described, focusing on the display area DA.

The substrate 110 may be made of a material having a flexible characteristic capable of bending, folding, rolling, or the like. The substrate 110 may be formed of an insulating material such as a polymer resin. For example, the substrate 110 may be made of polyimide.

The circuit layer 120 may include the circuit elements constituting the pixel circuit of each pixel PX and the wires LI. FIG. 6 illustrates one transistor TR of the circuit elements provided in each pixel PX. The transistor TR may be disposed in a pixel region PXA of a corresponding pixel PX, and may be electrically connected to a light emitting element ED of the corresponding pixel PX. The transistor TR may include an active layer ACT, a gate electrode GE, a source electrode SE, and a drain electrode DE.

The circuit layer 120 may include conductive layers for forming the circuit elements and the wires LI, at least one semiconductor layer, and insulating layers disposed between the conductive layers and the semiconductor layer. For example, the circuit layer 120 may include a first insulating layer 121 (e.g., buffer layer), a semiconductor layer (or first semiconductor layer), a second insulating layer 122 (e.g., first gate insulating layer), a first conductive layer (e.g., first gate conductive layer), a third insulating layer 123 (e.g., second gate insulating layer), a second conductive layer (e.g., second gate conductive layer), a fourth insulating layer 124 (e.g., interlayer insulating layer or first interlayer insulating layer), a third conductive layer (e.g., first source-drain conductive layer), a fifth insulating layer 125 (e.g., first via layer or first planarization layer), a fourth conductive layer (e.g., second source-drain conductive layer), a sixth insulating layer 126 (e.g., second via layer or second planarization layer), and a seventh insulating layer 127 (e.g., third via layer or third planarization layer), which are sequentially disposed on the substrate 110 along the third direction DR3.

The first insulating layer 121 may include at least one inorganic layer containing an inorganic insulating material (e.g., silicon nitride, silicon oxide, silicon oxynitride, titanium oxide, aluminum oxide, or another inorganic insulating material). However, embodiments are not limited thereto, and the material of the first insulating layer 121 may be changed.

In an embodiment, an additional conductive layer may be disposed between the substrate 110 and the first insulating layer 121. For example, a conductive layer including at least one wire LI (or a part of the at least one wire LI) or a bottom metal layer BML overlapping the active layer ACT of at least one transistor TR may be disposed between the substrate 110 and the first insulating layer 121.

The semiconductor layer may include the active layer ACT of each of the transistors TR. The semiconductor layer may include polycrystalline silicon, monocrystalline silicon, low-temperature polycrystalline silicon, amorphous silicon, or an oxide semiconductor material. Each active layer ACT may include a channel region, a source region, and a drain region.

The second insulating layer 122 may include at least one inorganic layer containing an inorganic insulating material. The material of the second insulating layer 122 may be changed according to embodiments.

The first conductive layer may include the gate electrode GE of each of the transistors TR. Each gate electrode may include a conductive material (e.g., at least one of molybdenum (Mo), aluminum (Al), chromium (Cr), gold (Au), titanium (Ti), nickel (Ni), neodymium (Nd), copper (Cu), or other metals, an alloy thereof, or other conductive materials) and may be a single layer or multilayer electrode.

The first conductive layer may further include at least one wire LI (or a part of the at least one wire LI) including a conductive material, a bridge pattern, or a capacitor electrode. For example, the first conductive layer may include a part (or sub-line) of each of at least some of the first lines SL and the data lines DL. In an embodiment, the first lines SL may be formed in the first conductive layer between the bending area BA and the embedded circuit SDR, and may optionally further include a sub-line formed on another conductive layer (e.g., the second conductive layer or the third gate conductive layer) and connected to a main line. In an embodiment, the data lines DL may be formed alternately in the first and second conductive layers between the bending area BA and the display area DA. Accordingly, the data lines DL may be more densely arranged while ensuring insulation between the data lines DL.

The third insulating layer 123 may include at least one inorganic layer, including an inorganic insulating material. The material of the third insulating layer 123 may be changed according to embodiments.

The second conductive layer may further include at least one wire LI (or a part of the at least one wire LI) including a conductive material, a bridge pattern, or a capacitor electrode. For example, the second conductive layer may include a part (or sub-line) of each of at least some of the first lines SL or the data lines DL. In an embodiment, when each pixel PX or the embedded circuit SDR further includes at least one transistor formed on a different layer from the transistors TR shown in FIG. 5, the second conductive layer may further include a bottom metal layer or a gate electrode of the at least one transistor.

The fourth insulating layer 124 may include at least one inorganic layer including an inorganic insulating material. The material of the fourth insulating layer 124 may be changed according to embodiments.

The third conductive layer may include the source electrode SE and the drain electrode DE of each of the transistors TR. Each of the source electrode SE and drain electrode DE may include a conductive material and may be a single layer or multilayer electrode. In another embodiment, the source electrode SE and the drain electrode DE of each of the transistors TR may be formed as the source region and the drain region of the active layer ACT, and the third conductive layer may include a bridge pattern connected to the source electrode SE or the drain electrode DE of at least one transistor TR, or the like.

The third conductive layer may further include at least one wire LI (or a part of the at least one wire LI) including a conductive material, a bridge pattern, or a capacitor electrode. For example, the third conductive layer may include a first wiring layer VDL1 of the first power line VDL and a first wiring layer VSL1 of the second power line VSL.

The fifth insulating layer 125 may include at least one organic layer containing an organic insulating material (e.g., acrylic resin, epoxy resin, phenolic resin, polyamide resin, polyimide resin, or another organic insulating material) to planarize the circuit layer 120. The organic insulating material constituting the fifth insulating layer 125 may be variously changed according to embodiments.

The fourth conductive layer may include first connection electrodes CNE1 (or connection electrodes) respectively connecting the transistors TR to the light emitting elements ED. The first connection electrodes CNE1 may be respectively disposed on the transistors TR and may each electrically connect the transistor TR to the light emitting element ED of the corresponding pixel PX. Each of the first connection electrodes CNE1 may include a conductive material and may be a single layer or multilayer electrode.

The fourth conductive layer may further include at least one wire LI (or a part of the at least one wire LI) including a conductive material, or a bridge pattern. For example, the fourth conductive layer may include a second wiring layer VDL2 of the first power line VDL and a second wiring layer VSL2 of the second power line VSL.

Each of the sixth insulating layer 126 and the seventh insulating layer 127 may include at least one organic layer containing an organic insulating material (e.g., the organic insulating material exemplified as the material of the fifth insulating layer 125 or another organic insulating material) to planarize the circuit layer 120. The organic insulating material constituting the sixth insulating layer 126 and the seventh insulating layer 127 may be variously changed according to embodiments. In an embodiment, the sixth insulating layer 126 and the seventh insulating layer 127 may be integrated into a single insulating layer.

The light emitting element layer 130 may include the light emitting elements ED located in the emission areas EA. The light emitting element layer 130 may further include a pixel defining layer 131 that partitions the emission areas EA, and a spacer 132 disposed on a part of the pixel defining layer 131.

Each light emitting element ED may include a first electrode AE (e.g., anode electrode) connected to the transistor TR through the first connection electrode CNE1 or the like, and a light emitting layer EML and a second electrode CE (e.g., cathode electrode) sequentially disposed on the first electrode AE. In an embodiment, the light emitting element ED may further include a first intermediate layer (e.g., hole layer including a hole transport layer) interposed between the first electrode AE and the light emitting layer EML, and a second intermediate layer (e.g., an electron layer including an electron transport layer) interposed between the light emitting layer EML and the second electrode CE.

The first electrode AE of the light emitting element ED may include a conductive material and may be disposed on the circuit layer 120. For example, the first electrode AE may be disposed on the seventh insulating layer 127 to correspond to each emission area EA. In an embodiment, the first electrode AE may include a metallic material having high reflectivity. For example, the first electrode AE may have a single-layer structure of molybdenum (Mo), titanium (Ti), copper (Cu) or aluminum (Al), or may have a multilayer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element ED may include a high molecular material or a low molecular material. Light emitted from the light emitting layer EML may contribute to image display. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by pixels PX of different colors, and a wavelength conversion layer or color filters corresponding to the color (or wavelength band) of light desired to be emitted from each pixel PX may be arranged in the emission areas EA of at least some of the pixels PX.

The second electrode CE of the light emitting element ED may include a conductive material and may be connected to the second power line VSL. In an embodiment, the second electrode CE may be a common layer formed across the entire display area DA to cover the light emitting layer EML and the pixel defining layer 131. In an embodiment, the second electrode CE may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the second electrode CE is made of a semi-transmissive conductive material, an improvement in light output efficiency due to a micro cavity effect may be expected.

The pixel defining layer 131 may have an opening corresponding to each of the emission areas EA and may surround the emission areas EA. For example, the pixel defining layer 131 may be formed to cover the edge of the first electrode AE of each of the light emitting elements ED and may include an opening that exposes the remaining part of the first electrode AE. A region where the exposed first electrode AE and the light emitting layer EML overlap (or a region including the same) may be defined as the emission area EA of each pixel PX.

The pixel defining layer 131 may include at least one organic layer containing an organic insulating material. In an embodiment, the pixel defining layer 131 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB). The organic insulating material constituting the pixel defining layer 131 is not particularly limited and may be variously changed according to embodiments.

The spacer 132 may be disposed on a part of the pixel defining layer 131. For example, the spacer 132 may be regularly or irregularly distributed in the non-emission area NEA.

The spacer 132 may include at least one organic layer containing an organic insulating material. The spacer 132 may include the same material as the pixel defining layer 131 or may include a different material from the pixel defining layer 131. In an embodiment, the pixel defining layer 131 and the spacer 132 may be sequentially formed through separate mask processes. In another embodiment, the pixel defining layer 131 and the spacer 132 may be simultaneously formed using a halftone mask. In this case, the pixel defining layer 131 and the spacer 132 may be regarded as a single insulating layer that is integral with each other. The organic insulating material constituting the spacer 132 is not particularly limited and may be variously changed according to embodiments.

The encapsulation layer 140 may be disposed on the light emitting element layer 130 in the display area DA and the non-display area NA around the display area DA. The encapsulation layer 140 may block the permeation of oxygen or moisture into the light emitting element layer 130, and may reduce electrical or physical impacts to the circuit layer 120 and the light emitting element layer 130.

In an embodiment, the encapsulation layer 140 may include a first encapsulation layer 141, a second encapsulation layer 142, and a third encapsulation layer 143 sequentially disposed on the light emitting element layer 130. The first encapsulation layer 141 and the third encapsulation layer 143 may include an inorganic insulating material, and the second encapsulation layer 142 may include an organic insulating material.

In an embodiment, the second encapsulation layer 142 may be prepared by dropping an organic material in a liquid state onto the first encapsulation layer 141, spreading it to cover the display area DA, and then curing it. In addition, the display panel 100 may include at least one dam DM for limiting the diffusion range of the organic material of the second encapsulation layer 142. The dam DM may be disposed in the non-display area NA adjacent to the display area DA so as to surround the display area DA. For example, the dam DM may be disposed in the first non-display area NA1.

The second encapsulation layer 142 may extend to an area where the at least one dam DM is disposed. Accordingly, the first encapsulation layer 141 and the third encapsulation layer 143 may be bonded at the periphery of the dam DM.

The sensor layer 150 may be disposed on the encapsulation layer 140. The sensor layer 150 may include the sensing patterns SSP and at least one insulating layer. For example, the sensor layer 150 may include a buffer layer 151 disposed on the encapsulation layer 140, the bridge electrodes BE disposed on the buffer layer 151, an insulating layer 152 (e.g., a sensor insulating layer) disposed on the bridge electrodes BE, the driving electrodes TE and sensing electrodes RE disposed on the insulating layer 152, and an overcoat layer 153 disposed on the driving electrodes TE and sensing electrodes RE. The positions of the bridge electrodes BE, the driving electrodes TE, and the sensing electrodes RE may vary according to embodiments. For example, the driving electrodes TE and the sensing electrodes RE may be disposed on the buffer layer 151 and the bridge electrodes BE may be disposed on the insulating layer 152. In another embodiment, the driving electrodes TE and the sensing electrodes RE may be disposed on different layers with the insulating layer 152 interposed therebetween, and the bridge electrodes BE may be integral with the driving electrodes TE.

Each of the buffer layer 151 and the insulating layer 152 may include at least one inorganic layer including an inorganic insulating material.

The overcoat layer 153 may be made of an organic insulating material that can be disposed in a low-temperature process. For example, the overcoat layer 153 may be made of a negative photoresist material.

The bridge electrodes BE, the driving electrodes TE, and the sensing electrodes RE may include a conductive material and may each be formed of a single layer or multiple layers.

The driving electrodes TE and the sensing electrodes RE may be respectively connected to the second lines TL. In an embodiment, the second lines TL may be formed simultaneously with the driving electrodes TE and the sensing electrodes RE. In this case, the second lines TL may be disposed in the same layer as the driving electrodes TE and the sensing electrodes RE, and may include the same material. In one example, each second line TL may be integrally formed with one driving electrode TE or one sensing electrode RE. The second lines TL may be located on the encapsulation layer 150 in a region where the encapsulation layer 150 is provided, and may extend or be connected to a region (e.g., the second non-display area NA2) where the encapsulation layer 150 is not provided to be connected to the second pads TP.

At least one dam DM and the bank BNK may be disposed in the non-display area NA. For example, the first dam DM1 and the second dam DM2 may be sequentially disposed in the non-display area NA (e.g., the first non-display area NA1) adjacent to the display area DA, and the bank BNK may be disposed at the outer side of the second dam DM2.

Each dam DM and the bank BNK may be simultaneously formed using the same material as at least one organic layer located in the display area DA. For example, each dam DM and the bank BNK may be simultaneously formed using the same material as at least one organic layer of the fifth insulating layer 125, the sixth insulating layer 126, the seventh insulating layer 127, the pixel defining layer 131, or the spacer 132.

Each dam DM may surround the display area DA in plan view. The bank BNK may be disposed at the periphery of one end (e.g., a lower edge region close to the sub-region SBA) of the dam DM and the display area DA. In one example, the bank BNK may be disposed in the non-display area NA below the display area DA so as to be adjacent to one sidewall (e.g., one sidewall below the display area DA) of the second dam DM2, and may be spaced apart from the display area DA by a greater distance than the second dam DM2 is.

In an embodiment, the first dam DM1 may be a double structure or a multi-structure dam. For example, two or more first dams DM1 may surround the display area DA.

Each first dam DM1 may include at least one organic layer. In an embodiment, each first dam DM1 may have a multilayer structure with at least two organic layers stacked. In an embodiment, each first dam DM1 may include a first dam layer DML11 and a second dam layer DML12 disposed on the first dam layer DML11. For example, the first dam layer DML11 may include the same material as the sixth insulating layer 126 or the seventh insulating layer 127 and may be formed in substantially the same layer as the sixth insulating layer 126 or the seventh insulating layer 127. In this case, the first dam layer DML11 may be considered as a part of the sixth insulating layer 126 or the seventh insulating layer 127. The second dam layer DML12 may include the same material as the pixel defining layer 131 or the spacer 132 and may be formed in substantially the same layer as the pixel defining layer 131 or the spacer 132. In this case, the second dam layer DML12 may be considered as a part of the pixel defining layer 131 or the spacer 132.

The second dam DM2 may include at least one organic layer. In an embodiment, the second dam DM2 may have a multilayer structure with at least two organic layers stacked. For example, the second dam DM2 may include a first dam layer DML21, a second dam layer DML22 disposed on the first dam layer DML21, and a third dam layer DML23 disposed on the second dam layer DML22. The first dam layer DML21 may include the same material as the fifth insulating layer 125 and may be formed in substantially the same layer as the fifth insulating layer 125. In this case, the first dam layer DML21 may be considered as a part of the fifth insulating layer 125. The second dam layer DML22 may include the same material as the sixth insulating layer 126 or the seventh insulating layer 127 and may be formed in substantially the same layer as the sixth insulating layer 126 or the seventh insulating layer 127. In this case, the second dam layer DML22 may be considered as a part of the sixth insulating layer 126 or the seventh insulating layer 127. The third dam layer DML23 may include the same material as the pixel defining layer 131 or the spacer 132 and may be formed in substantially the same layer as the pixel defining layer 131 or the spacer 132. In this case, the third dam layer DML23 may be considered as a part of the pixel defining layer 131 or the spacer 132.

Since at least one dam DM is spaced apart from the display area DA, a valley may be formed between a dam area where the at least one dam DM is formed and the display area DA and between adjacent dams DM. The valley may limit an area in which the second encapsulation layer 142 diffuses. The first encapsulation layer 141 and the third encapsulation layer 143 may be formed only up to a part (e.g., a part between the display area DA and the bending area BA) of the bank BNK adjacent to the dam DM. For example, the lower edge regions of the first encapsulation layer 141 and the third encapsulation layer 143 may be disposed on a part of the bank BNK adjacent to the dam DM.

The bank BNK may be disposed in the bending area BA or around the bending area BA, and may include at least one organic layer. In the bending area BA, inorganic layers (e.g., the first, second, third, and fourth insulating layers 121, 122, 123, and 124 of the circuit layer 120, and the buffer layer 151 and insulating layer 152 of the sensor layer 150) may be removed. Accordingly, cracks may be prevented from occurring in the inorganic layers which are relatively susceptible to bending stress. The bank BNK may cover an opening formed in the inorganic layers in the bending area BA, and may protect the wires LI passing through the bending area BA.

The bank BNK may include at least one organic layer. In an embodiment, the bank BNK may have a multilayer structure with at least two organic layers stacked. For example, the bank BNK may include at least one lower bank layer that is disposed in the same layer as, or is a part of, at least one organic layer (also referred to as a “first organic layer”) formed on the circuit layer 120 in the display area DA, and at least one upper bank layer that overlaps the lower bank layer and is disposed in the same layer as, or is a part of, at least one organic layer (also referred to as a “second organic layer”) formed on the light emitting element layer 130 in the display area DA.

In an embodiment, the bank BNK may include a first bank layer BNL1, a second bank layer BNL2 disposed on the first bank layer BNL1, a third bank layer BNL3 disposed on the second bank layer BNL2, a fourth bank layer BNL4 disposed on the third bank layer BNL3, and a fifth bank layer BNL5 disposed on the fourth bank layer BNL4. The structure of the bank BNK is not limited thereto, and may be variously changed according to embodiments. For example, the bank BNK may not include at least one of the first bank layer BNL1, the second bank layer BNL2, the third bank layer BNL3, the fourth bank layer BNL4, or the fifth bank layer BNL5. Alternatively, at least two of the first bank layer BNL1, the second bank layer BNL2, the third bank layer BNL3, the fourth bank layer BNL4, or the fifth bank layer BNL5 may be integrated into a single bank layer.

In an embodiment, the first bank layer BNL1 may include the same material as the fifth insulating layer 125, and may be formed in substantially the same layer as the fifth insulating layer 125. The first bank layer BNL1 may also be considered as a part of the fifth insulating layer 125.

In an embodiment, the second bank layer BNL2 may include the same material as the sixth insulating layer 126, and may be formed in substantially the same layer as the sixth insulating layer 126. The second bank layer BNL2 may also be considered as a part of the sixth insulating layer 126.

In an embodiment, the third bank layer BNL3 may include the same material as the seventh insulating layer 127, and may be formed in substantially the same layer as the seventh insulating layer 127. The third bank layer BNL3 may also be considered as a part of the seventh insulating layer 127.

In an embodiment, the fourth bank layer BNL4 may include the same material as the pixel defining layer 131 and may be formed in substantially the same layer as the pixel defining layer 131. The fourth bank layer BNL4 may also be considered as a part of the pixel defining layer 131.

In an embodiment, the fifth bank layer BNL5 may include the same material as the spacer 132, and may be formed in substantially the same layer as the spacer 132. The fifth bank layer BNL5 may also be considered as a part of the spacer 132.

The stacked structure and material of the bank BNK are not limited to those of the above-described embodiment. For example, the stacked structure and material of the bank BNK may be variously changed according to embodiments.

In an embodiment, the wires LI passing through the bending area BA may be provided to the fourth conductive layer (e.g., a second source-drain conductive layer including the first connection electrodes CNE1) in the bending area BA. When a part of each of the wires LI located in the bending area BA is referred to as a second sub-line SLI2, each of the second sub-lines SLI2 may be disposed on the first bank layer BNL1 that is substantially the same layer as the fifth insulating layer 125 and may be covered with the second bank layer BNL2 that is substantially the same layer as the sixth insulating layer 126.

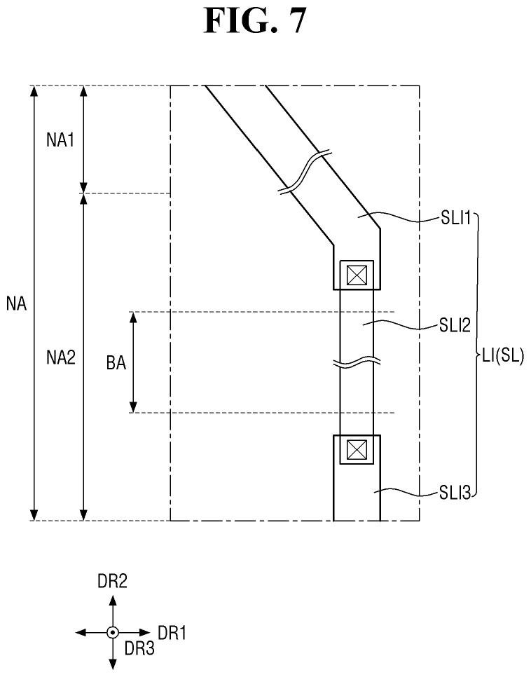

FIG. 7 is a plan view schematically illustrating wires LI according to an embodiment. For example, FIG. 7 schematically illustrates a part of one first line SL, representative of the wires LI of FIG. 4 that pass through the bending area BA.

Referring to FIGS. 4, 6, and 7, the wire LI may include the second sub-line SLI2 located in the bending area BA, and a first sub-line SLI1 and a third sub-line SLI3 located on both sides of the second sub-line SLI2. The first sub-line SLI1 and the third sub-line SLI3 may be provided in a different conductive layer from the second sub-line SLI2, and may be electrically connected to the second sub-line SLI2 through at least one contact hole or the like. In an embodiment, each of the wires LI passing through the bending area BA may be connected (or extend) from the sub-region SBA to the main region MA. For example, each of the wires LI may be connected from each pad PD (an area where the display driving circuit 200 is mounted in the case of the data line DL) located in the pad area PA to the first non-display area NA1 via the second non-display area NA2 including the bending area BA.

The first sub-line SLI1 may be located between the main region MA including the first non-display area NA1 and the bending area BA of the second non-display area NA2.

In an embodiment, when the first sub-line SLI1 is a part of the first line SL, the first sub-line SLI1 may be provided in the first conductive layer (e.g., first gate conductive layer) of the circuit layer 120. For example, the first sub-line SLI1 may be disposed on the second insulating layer 122 with the gate electrodes GE of the transistors TR. The first sub-line SLI1 may be a single layer or multilayer wire. For example, the first sub-line SLI1 may be a single layer wire provided in the first conductive layer of the circuit layer 120, or may be a double layer or triple layer wire provided in the first conductive layer, the second conductive layer (e.g., second gate conductive layer), or another conductive layer (e.g., third gate conductive layer when the circuit layer 120 includes the third gate conductive layer) of the circuit layer 120.

In an embodiment, when the first sub-line SLI1 is a part of the first power line VDL or the second power line VSL, the first sub-line SLI1 may be provided in the third conductive layer (e.g., first source-drain conductive layer) or the fourth conductive layer (e.g., second source-drain conductive layer) of the circuit layer 120.

In an embodiment, when the first sub-line SLI1 is a part of the data line DL (or data connection line), the first sub-line SLI1 may be provided in the first conductive layer or the second conductive layer of the circuit layer 120. The data line DL may be provided in the third conductive layer in the display area DA.

The second sub-line SLI2 may be located in the bending area BA. In an embodiment, the second sub-line SLI2 may be provided in the fourth conductive layer (e.g., second source-drain conductive layer) of the circuit layer 120. For example, the second sub-line SLI2 may be disposed on the seventh insulating layer 127 (or the sixth insulating layer 126 when the circuit layer 120 does not include the seventh insulating layer 127) together with the first connection electrodes CNE1. In an embodiment, the second sub-line SLI2 may be a single layer wire.

The third sub-line SLI3 may be located between the bending area BA of the second non-display area NA2 and the pad area PA (an area where the display driving circuit 200 is mounted when the third sub-line SLI3 is a part of the data line DL).

In an embodiment, when the third sub-line SLI3 is a part of the first line SL, the third sub-line SLI3 may be provided in the first conductive layer (e.g., first gate conductive layer) of the circuit layer 120. The third sub-line SLI3 may be a single layer or multilayer wire. For example, the third sub-line SLI3 may be a single layer wire provided in the first conductive layer of the circuit layer 120, or may be a double layer or triple layer wire provided in the first conductive layer, the second conductive layer (e.g., second gate conductive layer), or another conductive layer (e.g., third gate conductive layer when the circuit layer 120 includes the third gate conductive layer) of the circuit layer 120.

In an embodiment, when the third sub-line SLI3 is a part of the first power line VDL or the second power line VSL, the third sub-line SLI3 may be provided in the third conductive layer (e.g., first source-drain conductive layer) or the fourth conductive layer (e.g., second source-drain conductive layer) of the circuit layer 120.

In an embodiment, when the third sub-line SLI3 is a part of the data line DL (or data connection line), the third sub-line SLI3 may be provided in the first conductive layer or the second conductive layer of the circuit layer 120.

The location or structure of the wires LI for each area are not limited to those of the above-described embodiment, and may be variously changed according to embodiments.

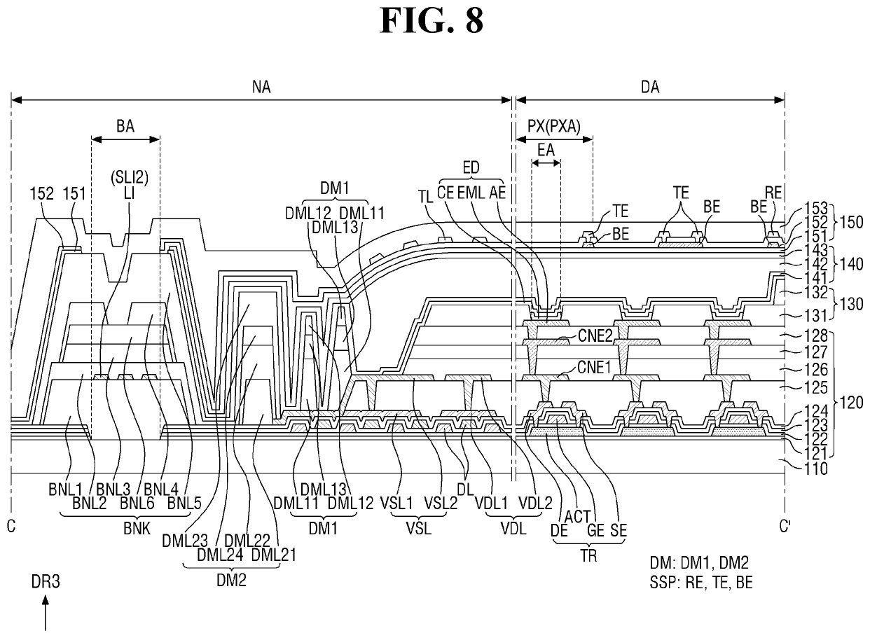

FIG. 8 is a cross-sectional view illustrating the display panel 100 according to an embodiment. For example, FIG. 8 is a schematic illustration of an embodiment of a cross section taken along line C-C′ of FIG. 4, and illustrates a modification to the embodiment of FIG. 6.

Referring to FIGS. 6 and 8, the circuit layer 120 may further include at least one conductive layer and at least one organic layer. For example, the circuit layer 120 may further include an eighth insulating layer 128 (e.g., fourth via layer or fourth planarization layer) and a fifth conductive layer (e.g., third source-drain conductive layer) disposed on the seventh insulating layer 127 and including second connection electrodes CNE2.

The second connection electrodes CNE2 may be respectively disposed on the first connection electrodes CNE1, and may each electrically connect the first connection electrode CNE1 to the light emitting element ED of the corresponding pixel PX. Each of the second connection electrodes CNE2 may include a conductive material and may be a single layer or multilayer electrode.

In an embodiment, the fifth conductive layer may further include at least one wire LI (or a part of the at least one wire LI) including a conductive material, or a bridge pattern. In one example, at least one of the first power line VDL or the second power line VSL may further include an additional wiring layer provided in the fifth conductive layer together with the second connection electrodes CNE2.

The eighth insulating layer 128 may include at least one organic layer containing an organic insulating material (e.g., the organic insulating material exemplified as the material of the fifth insulating layer 125 or another organic insulating material) to planarize the circuit layer 120. The organic insulating material constituting the eighth insulating layer 128 may be variously changed according to embodiments.

In an embodiment, at least one dam DM may further include an additional dam layer formed in substantially the same layer as the eighth insulating layer 128. For example, the first dam DM1 may further include a third dam layer DML13 disposed between the first dam layer DML11 and the second dam layer DML12 and containing the same material as the eighth insulating layer 128. Similarly, the second dam DM2 may further include a fourth dam layer DML24 disposed between the second dam layer DML22 and the third dam layer DML23 and containing the same material as the eighth insulating layer 128.

In an embodiment, the bank BNK may further include an additional bank layer formed in substantially the same layer as the eighth insulating layer 128. For example, the bank BNK may further include a sixth bank layer BNL6 disposed between the third bank layer BNL3 and the fourth bank layer BNL4 and containing the same material as the eighth insulating layer 128.

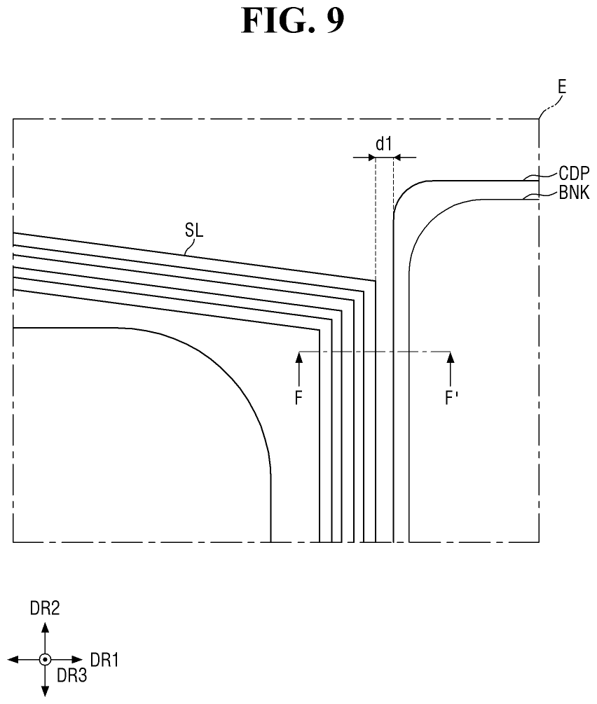

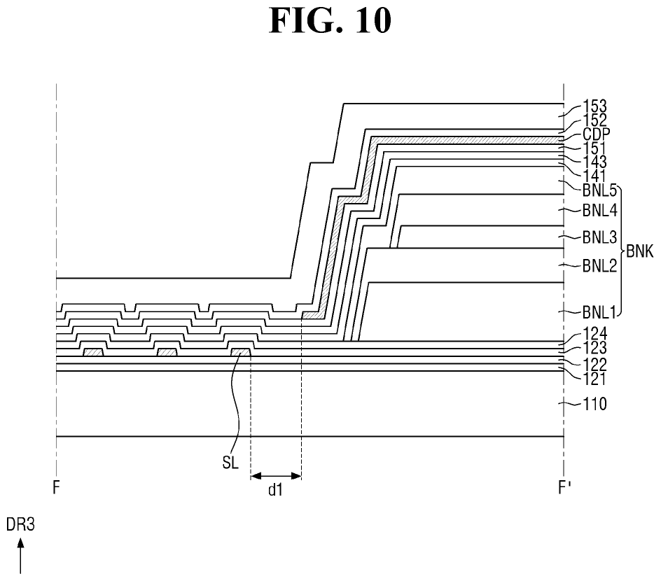

FIG. 9 is a plan view schematically showing part E of FIG. 4. FIG. 10 is a cross-sectional view illustrating an embodiment of a cross section corresponding to line F-F′ of FIG. 9.

Referring to FIGS. 9 and 10 in addition to FIGS. 1 to 8, a part of the encapsulation layer 140, e.g., a part of the first encapsulation layer 141 and a part of the third encapsulation layer 143, may be located on the bank BNK and may include an inclined portion (or stepped portion) by the bank BNK. For example, in part E of FIG. 4 or a peripheral region thereof, the first encapsulation layer 141 and the third encapsulation layer 143 may be located on the bank BNK, and may include an inclined portion (or stepped portion) by the bank BNK. In one example, the first encapsulation layer 141 and the third encapsulation layer 143 may include an inclined portion due to a step that occurs at the end of at least one bank layer constituting the bank BNK.

The conductive pattern CDP may be disposed on the inclined portion of the encapsulation layer 140 on at least one end (e.g., both ends in the first direction DR1) of the bank. In an embodiment, the conductive pattern CDP may be formed simultaneously using the same material as patterns disposed in a lower layer among the sensing patterns SSP provided on the sensor layer 150, e.g., as the bridge electrodes BE in the process of forming the bridge electrodes BE of FIGS. 5 and 6, thereby protecting the encapsulation layer 140 in subsequent processes. For example, in a process of forming the contact portions TCNT performed after the formation of the bridge electrodes BE, even if a photoresist pattern covers an area where the contact portions TCNT are not formed, the thickness of the photoresist pattern may be relatively small since the encapsulation layer 140 includes the inclined portion on both ends of the bank BNK. Accordingly, if the conductive pattern CDP is not provided, there is a risk of damage to the encapsulation layer 140 (e.g., third encapsulation layer 143) during the etching process using the photoresist pattern. However, according to an embodiment, by covering the inclined portion of the encapsulation layer 140 by the bank BNK with the conductive pattern CDP, the encapsulation layer 140 may be prevented from being unintentionally etched or damaged.

In the embodiment of FIGS. 4 to 10, at least one wire LI adjacent to at least one end of the bank BNK, e.g., at least one wire LI passing through a region between the edge of the substrate 110 and the conductive pattern CDP, may pass through a region adjacent to the conductive pattern CDP and may be spaced apart from the conductive pattern CDP in plan view. For example, at least a part of the bank BNK and conductive pattern CDP may be located between the main region MA and the bending area BA, and the first sub-line SLI1 of the wire LI adjacent to at least one end of the bank BNK may bypass an area where the bank BNK and the conductive pattern CDP are disposed, pass the edge region (e.g., left or right edge region) of the second non-display area NA2, and extend to the first non-display area NA1. For example, the first lines SL passing through the edge region of the second non-display area NA2 may pass through an area adjacent to the conductive pattern CDP but may not overlap the bank BNK and the conductive pattern CDP. In an embodiment, the first lines SL may be spaced apart from the conductive pattern CDP by a distance of 3 μm or more in plan view. For example, a separation distance d1 between the conductive pattern CDP and the first line SL closest to the conductive pattern CDP in plan view may be 3 μm or more.

According to the above-described embodiment, damage to the display panel 100 caused by static electricity may be prevented or minimized. For example, part E in FIG. 4, which corresponds to a corner portion of an area where the main region MA and the sub-region SBA of the display panel 100 are in contact with each other, may be an area where the passivation layer 170 provided in the bending area BA is not provided, and thus may be an area that is relatively susceptible to damage by static electricity or the like. However, according to an embodiment, by ensuring that the wires SL and the conductive pattern CDP are spaced apart by a predetermined distance (e.g., 3 μm) or more without overlapping each other in an electrostatically susceptible portion, the first lines SL may be prevented from being burnt due to static electricity or the like. Accordingly, wiring defects (e.g., open defects) or damage to the display panel 100 may be prevented or minimized.

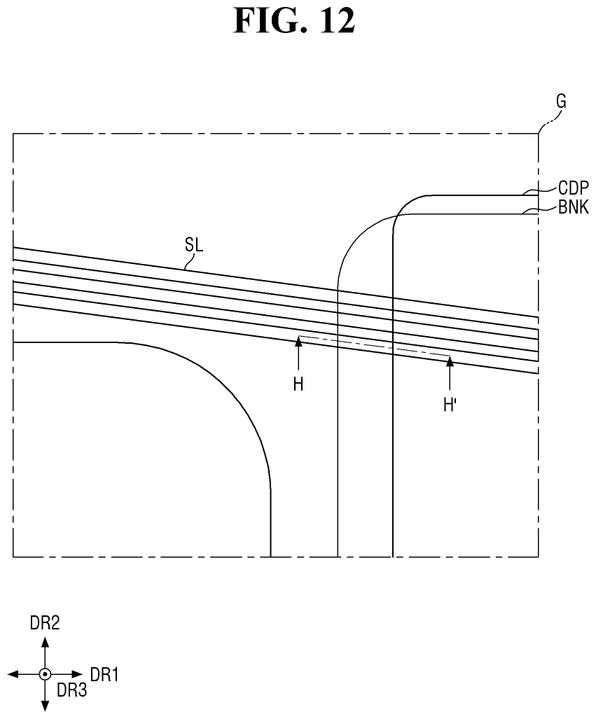

FIG. 11 is a plan view illustrating the display panel 100 according to an embodiment. FIG. 11 shows the display panel 100 in an unbent and unfolded state. FIG. 12 is a plan view schematically showing part G of FIG. 11.

In describing the embodiment of FIGS. 11 and 12, configurations that are substantially the same or similar to those of the embodiment of FIGS. 4 to 10 will be designated with the same reference numerals, and detailed descriptions thereof will be omitted.

Referring to FIGS. 11 and 12, at least one wire LI adjacent at least one end of the bank BNK may be connected (or extend) from the sub-region SBA to the main region MA via the area where the bank BNK and the conductive pattern CDP are disposed. The bank BNK may extend outward of the conductive pattern CDP in a plan view, and in a region where at least one wire LI and the conductive pattern CDP overlap, may cover the at least one wire LI.

For example, at least a part of the bank BNK and conductive pattern CDP may be located between the main region MA and the bending area BA, and the first lines SL adjacent to at least one end of the bank BNK may be connected from the sub-region SBA to the main region MA via under the bank BNK and the conductive pattern CDP. In one example, the first lines SL may be connected from the first pads SP located in the pad area PA to the main region MA via the bending area BA, and may overlap the bank BNK and the conductive pattern CDP between the bending area BA and the main region MA. The bank BNK may extend outward of the conductive pattern CDP in at least the first direction DR1 in plan view. For example, the bank BNK may include at least one organic layer that covers the first lines SL in a region where the first lines SL and the conductive pattern CDP overlap.

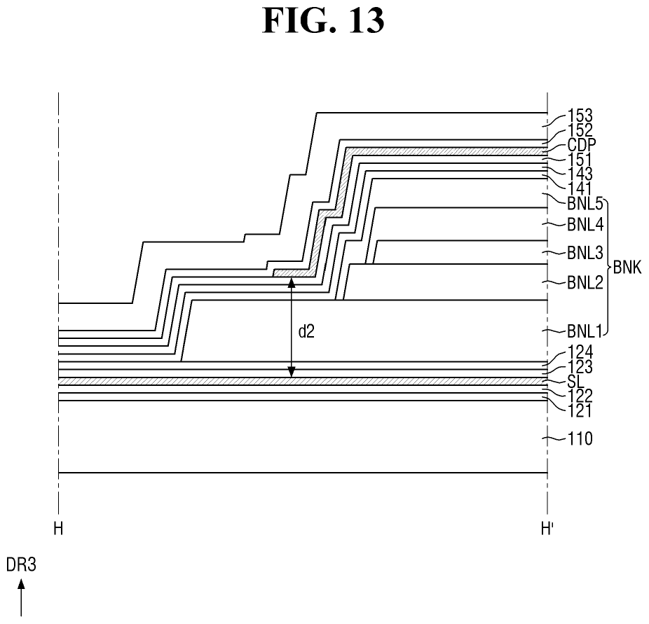

FIGS. 13 to 21 are cross-sectional views illustrating embodiments of a cross section corresponding to line H-H′ of FIG. 12. For example, FIGS. 13 to 21 illustrate different embodiments of a cross section corresponding to line H-H′ of FIG. 12.

Referring to FIGS. 13 to 21 in addition to FIGS. 11 and 12, at least one bank layer (e.g., at least one organic layer) of the bank layers forming the bank BNK may completely cover the first line SL in a region where the first line SL (or the first lines SL) and the conductive pattern CDP overlap. Further, the at least one bank layer may extend outward of the conductive pattern CDP in plan view.

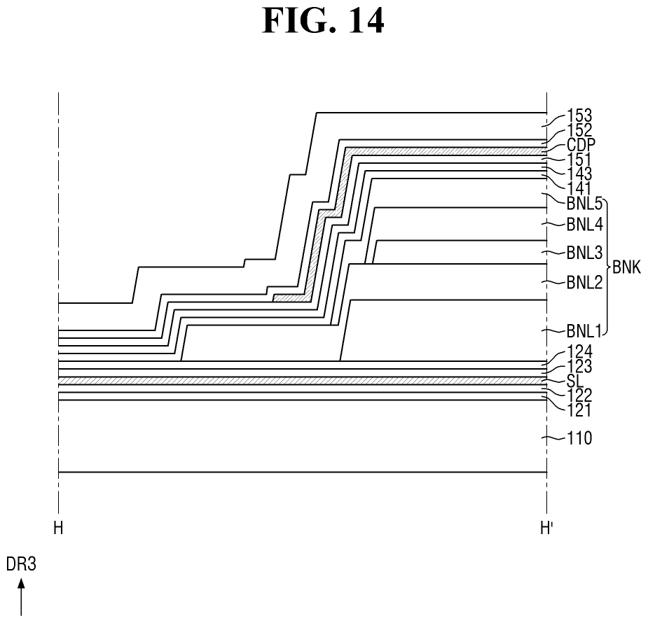

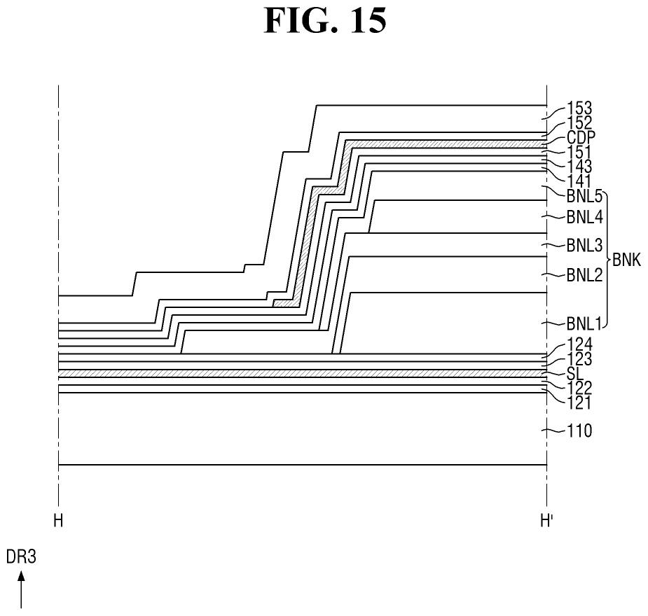

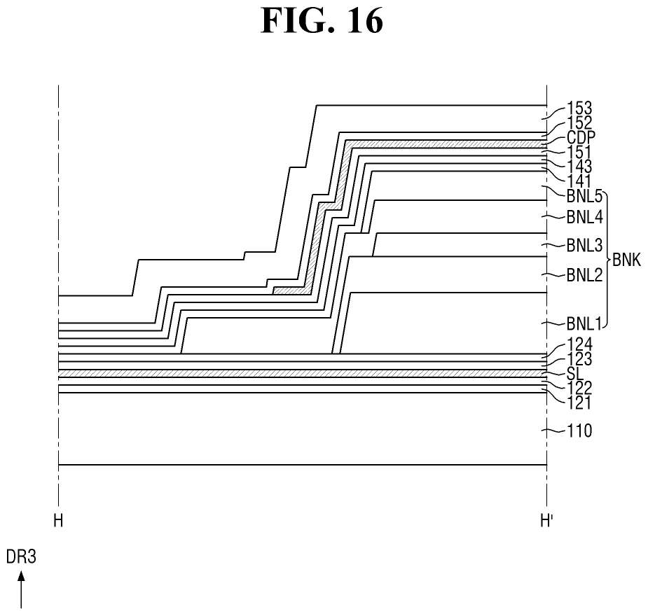

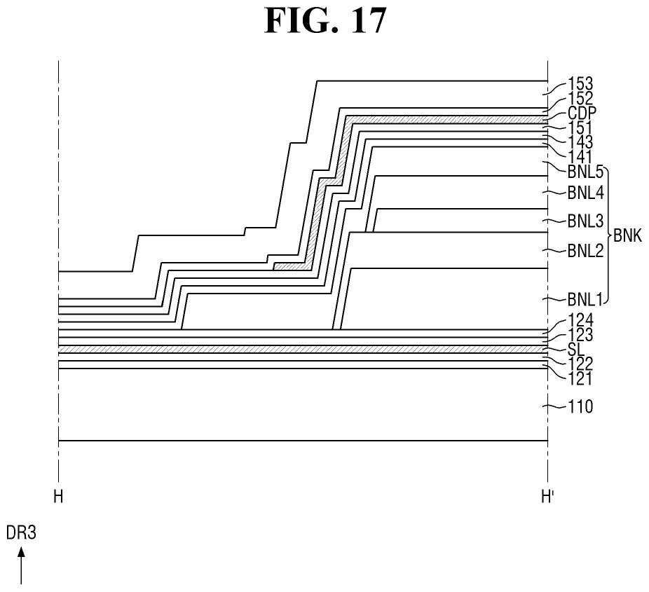

According to some embodiments, as shown in FIGS. 13 to 17, any one of the first bank layer BNL1, the second bank layer BNL2, the third bank layer BNL3, the fourth bank layer BNL4, and the fifth bank layer BNL5 may completely cover the first line SL in the region where the first line SL and the conductive pattern CDP overlap. For example, in the region where the first line SL and the conductive pattern CDP overlap, the first bank layer BNL1 may cover the first line SL as shown in FIG. 13, or the second bank layer BNL2 may cover the first line SL as shown in FIG. 14, or the third bank layer BNL3 may cover the first line SL as shown in FIG. 15, or the fourth bank layer BNL4 may cover the first line SL as shown in FIG. 16, or the fifth bank layer BNL5 may cover the first line SL as shown in FIG. 17. Further, the any one of the bank layers may extend outward of the conductive pattern CDP in at least the first direction DR1 in plan view.

According to other embodiments, at least two of the first bank layer BNL1, the second bank layer BNL2, the third bank layer BNL3, the fourth bank layer BNL4, or the fifth bank layer BNL5 may completely cover the first line SL in the region where the first line SL and the conductive pattern CDP overlap. Further, the at least two bank layers may extend outward of the conductive pattern CDP in at least the first direction DR1 in plan view.

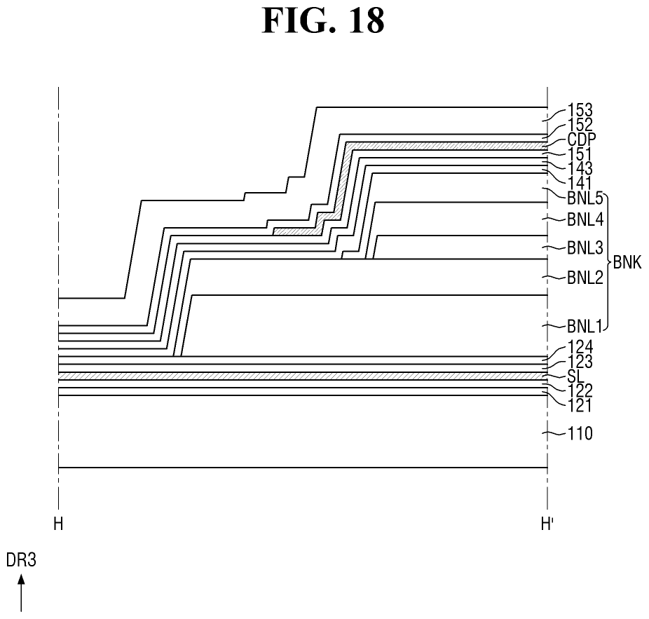

In an embodiment, as shown in FIG. 18, the first bank layer BNL1 and the second bank layer BNL2 may completely cover the first line SL in the region where the first line SL and the conductive pattern CDP overlap. Further, the first bank layer BNL1 and the second bank layer BNL2 may extend outward of the conductive pattern CDP in at least the first direction DR1 in plan view. Other than the combination of the first bank layer BNL1 and the second bank layer BNL2, two bank layers according to a possible combination of the bank layers constituting the bank BNK may completely cover the first line SL in the region where the first line SL and the conductive pattern CDP overlap.

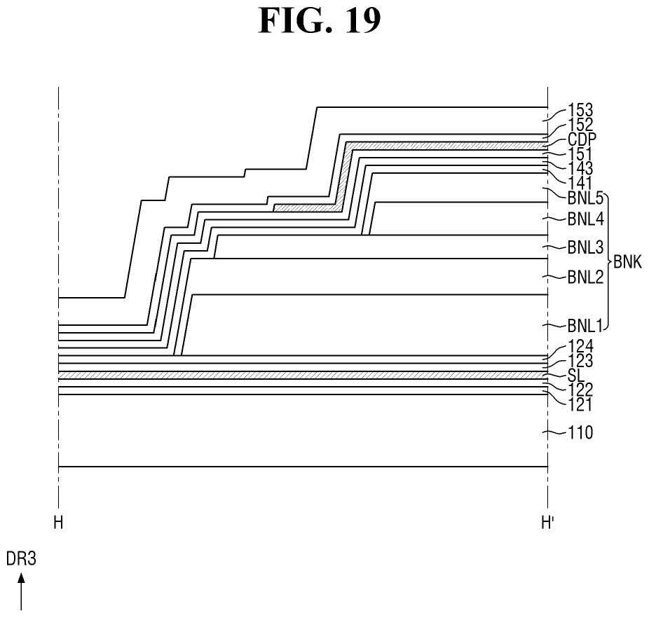

In an embodiment, as shown in FIG. 19, the first bank layer BNL1, the second bank layer BNL2, and the third bank layer BNL3 may completely cover the first line SL in the region where the first line SL and the conductive pattern CDP overlap. Further, the first bank layer BNL1, the second bank layer BNL2, and the third bank layer BNL3 may extend outward of the conductive pattern CDP in at least the first direction DR1 in plan view. Other than the combination of the first bank layer BNL1, the second bank layer BNL2, and the third bank layer BNL3, three bank layers according to a possible combination of the bank layers constituting the bank BNK may completely cover the first line SL in the region where the first line SL and the conductive pattern CDP overlap.

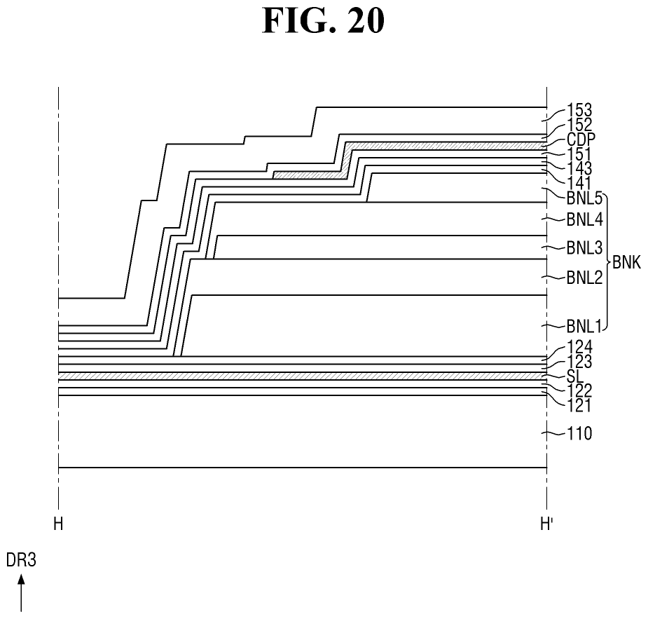

In an embodiment, as shown in FIG. 20, the first bank layer BNL1, the second bank layer BNL2, the third bank layer BNL3, and the fourth bank layer BNL4 may completely cover the first line SL in the region where the first line SL and the conductive pattern CDP overlap. Further, the first bank layer BNL1, the second bank layer BNL2, the third bank layer BNL3, and the fourth bank layer BNL4 may extend outward of the conductive pattern CDP in at least the first direction DR1 in plan view. Other than the combination of the first bank layer BNL1, the second bank layer BNL2, the third bank layer BNL3, and the fourth bank layer BNL4, four bank layers according to a possible combination of the bank layers constituting the bank BNK may completely cover the first line SL in the region where the first line SL and the conductive pattern CDP overlap.

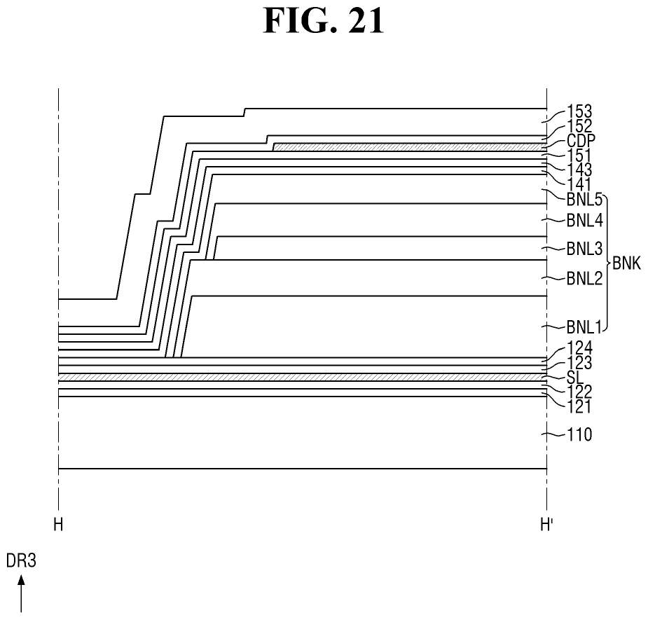

In an embodiment, as shown in FIG. 21, the first bank layer BNL1, the second bank layer BNL2, the third bank layer BNL3, the fourth bank layer BNL4, and the fifth bank layer BNL5 may completely cover the first line SL in the region where the first line SL and the conductive pattern CDP overlap. In one example, all bank layers constituting the bank BNK may completely cover the first line SL in the region where the first line SL and the conductive pattern CDP overlap. Further, the first bank layer BNL1, the second bank layer BNL2, the third bank layer BNL3, the fourth bank layer BNL4, and the fifth bank layer BNL5 may extend outward of the conductive pattern CDP in at least the first direction DR1 in plan view.

According to the above-described embodiment, damage to the display panel 100 caused by static electricity may be prevented or minimized. For example, in a portion susceptible to static electricity, such as part G in FIG. 11, a sufficient separation distance (e.g., d2 in FIG. 13) between the first line SL and the conductive pattern CDP may be secured by extending at least one bank layer that is included in the bank BNK and formed of an organic layer.

In an embodiment, the first line SL and the conductive pattern CDP may be spaced apart from each other by a distance of 3 μm or more with at least one bank layer included in the bank BNK interposed therebetween, in a thickness direction (e.g., the third direction DR3) of the substrate 110. For example, the sum of the thicknesses of the inorganic layers (e.g., third insulating layer 123, fourth insulating layer 124, first encapsulation layer 141, third encapsulation layer 143, and buffer layer 151) interposed between the first line SL and the conductive pattern CDP may be approximately 1.5 μm, and at least one bank layer included in the bank BNK may have a thickness of approximately 1.5 μm or more. In this case, by extending one bank layer or two or more bank layers to completely cover the first line SL between the first line SL and the conductive pattern CDP, a separation distance between the first line SL and the conductive pattern CDP may be secured to be 3 μm or more.

Accordingly, wiring defects (e.g., open defects) or damage to the display panel 100 caused by static electricity or the like may be prevented or minimized. Further, since wiring defects can be prevented even when the first line SL overlaps the bank BNK and the conductive pattern CDP, constraints on design space may be reduced or prevented, and space in the non-display area NA may be utilized more efficiently.

As described above, the display device 10 according to embodiments may include the conductive pattern CDP disposed on at least one end of the bank BNK and covering the encapsulation layer 140 on the at least one end of the bank BNK. Accordingly, damage to the encapsulation layer 140 may be prevented.

In an embodiment, the wire LI, e.g., the first line SL, adjacent to the conductive pattern CDP may be spaced apart from the conductive pattern CDP without overlapping the conductive pattern CDP in plan view. In another embodiment, the wire LI, e.g., the first line SL, adjacent to the conductive pattern CDP may pass under the bank BNK and the conductive pattern CDP so as to overlap the bank BNK and the conductive pattern CDP, and the bank BNK may include at least one organic layer covering the first line SL in the region where the first line SL and the conductive pattern CDP overlap. According to embodiments, by securing a sufficient separation distance between the conductive pattern CDP and the wire LI, wiring defects or damage to the display device 10 caused by static electricity or the like may be prevented or minimized.

Although embodiments of the present inventive concepts have been described, various modifications and similar arrangements of such embodiments will be apparent to a person of ordinary skill in the art. Accordingly, the inventive concepts are not limited to such embodiments, but rather to the scope and spirit of the appended claims.

What is claimed is:

1. A display device comprising:
a substrate comprising a main region and a sub-region, the main region comprises a display area in which pixels are arranged and a first non-display area around the display area, the sub-region protrudes from a side of the main region and comprises a second non-display area;
a circuit layer disposed on the substrate;
a light emitting element layer disposed on the circuit layer;
an encapsulation layer disposed on the light emitting element layer;
a sensor layer disposed on the encapsulation layer;
a bank located in a boundary region which is at or near where the first non-display area meets the second non-display area;
a conductive pattern disposed on at least one end of the bank and extending outward from the bank; and
a wire disposed in the circuit layer and connected from the sub-region to the main region,
wherein the wire passes through a region between an edge of the substrate and the conductive pattern, and is spaced apart from the conductive pattern in a plan view.

2. The display device of claim 1, wherein the wire is spaced apart from the conductive pattern by a distance of 3 μm or more in the plan view.

3. The display device of claim 1, wherein the sub-region further comprises a pad area located in the second non-display area, and
the wire is connected from a pad located in the pad area to the first non-display area via the second non-display area, and does not overlap the bank and the conductive pattern.

4. The display device of claim 1, wherein the second non-display area comprises a bending area spaced apart from the main region and in which the substrate is bent.

5. The display device of claim 4, wherein each of the pixels comprises:
a transistor disposed in the circuit layer and comprising a gate electrode, a source electrode, and a drain electrode; and
a light emitting element disposed in the light emitting element layer and electrically connected to the transistor,
wherein the wire comprises a first sub-line located between the main region and the bending area and formed from a same layer as the gate electrode.

6. The display device of claim 5, wherein at least a part of the conductive pattern and the bank is located between the main region and the bending area, and
the first sub-line passes through an edge region of the second non-display area bypassing an area where the bank and the conductive pattern are disposed.

7. The display device of claim 5, wherein the circuit layer further comprises a connection electrode disposed on the transistor and electrically connecting the transistor to the light emitting element, and
the wire further comprises a second sub-line located in the bending area and formed from a same layer as the connection electrode.

8. The display device of claim 1, wherein a part of the encapsulation layer is located on the bank and comprises an inclined portion by the bank, and
the conductive pattern is disposed on the inclined portion of the encapsulation layer.

9. The display device of claim 8, wherein the sensor layer comprises sensing patterns disposed on the encapsulation layer, and
the conductive pattern is formed from a same layer as at least one of the sensing patterns and contains a same material as the at least one sensing pattern.

10. The display device of claim 1, wherein the circuit layer comprises a first organic layer in the display area,
the light emitting element layer comprises a second organic layer in the display area, and
the bank comprises bank layers disposed in the same layer as the first organic layer and the second organic layer, respectively, and overlapping each other.

11. A display device comprising:
a substrate comprising a main region and a sub-region, the main region comprises a display area in which pixels are arranged and a first non-display area around the display area, the sub-region protrudes from a side of the main region and comprises a second non-display area;
a circuit layer disposed on the substrate;
a light emitting element layer disposed on the circuit layer;
an encapsulation layer disposed on the light emitting element layer;
a sensor layer disposed on the encapsulation layer;
a bank located in a boundary region which is at or near where the first non-display area meets the second non-display area;
a conductive pattern disposed on at least one end of the bank; and
a wire disposed in the circuit layer and connected from the sub-region to the main region under the bank and the conductive pattern,
wherein the bank extends outward from the conductive pattern in a plan view and comprises at least one organic layer covering the wire in a region where the wire and the conductive pattern overlap.

12. The display device of claim 11, wherein the wire and the conductive pattern are spaced apart from each other by a distance of 3 μm or more with the at least one organic layer interposed therebetween in a thickness direction of the substrate.

13. The display device of claim 11, wherein the circuit layer comprises a first organic layer in the display area,
the light emitting element layer comprises a second organic layer in the display area, and
the bank comprises bank layers disposed in the same layer as the first organic layer and the second organic layer, respectively, and overlapping each other.

14. The display device of claim 13, wherein at least one of the bank layers completely covers the wire in a region where the wire and the conductive pattern overlap, and extends outward of the conductive pattern in the plan view.

15. The display device of claim 11, wherein the second non-display area comprises a bending area spaced apart from the main region and in which the substrate is bent.

16. The display device of claim 15, wherein at least a part of the conductive pattern and the bank is located between the main region and the bending area, and
the wire is connected from a pad located in the sub-region to the main region via the bending area, and overlaps the bank and the conductive pattern between the main region and the bending area.

17. The display device of claim 15, wherein each of the pixels comprises:
a transistor disposed in the circuit layer and comprising a gate electrode, a source electrode, and a drain electrode; and
a light emitting element disposed in the light emitting element layer and electrically connected to the transistor,
wherein the wire comprises a first sub-line located between the main region and the bending area and formed from a same layer as the gate electrode.

18. The display device of claim 17, wherein the circuit layer further comprises a connection electrode disposed on the transistor and electrically connecting the transistor to the light emitting element, and
the wire further comprises a second sub-line located in the bending area and formed from a same layer as the connection electrode.

19. The display device of claim 11, wherein a part of the encapsulation layer is located on the bank and comprises an inclined portion at an end of the bank, and
the conductive pattern is disposed on the inclined portion of the encapsulation layer.

20. The display device of claim 19, wherein the sensor layer comprises sensing patterns disposed on the encapsulation layer, and
the conductive pattern is disposed in the same layer as at least one of the sensing patterns and contains the same material as the at least one sensing pattern.
